(19) United States
(12) Patent Application Publication
(10) Pub. No.: US 2026/0101551 A1
(43) Pub. Date: Apr. 9, 2026

(54) SEMICONDUCTOR DEVICE WITH ISOLATION STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: CHIEN-KAI WU, TAIPEI CITY (TW); MENG CHI HANG, HSINCHU CITY (TW); CHIEN-LIN TSENG, HSINCHU COUNTY (TW); CHUNG-CHUAN TSENG, HSINCHU CITY (TW)

(21) Appl. No.: 18/910,024

(22) Filed: Oct. 9, 2024

(51) Int. Cl. H01L 29/06; H01L 21/3065; H01L 21/762

(52) U.S. Cl. CPC H10D 62/126; H10P 50/242; H10W 10/014; H10W 10/17

(57) ABSTRACT

A semiconductor device is provided. The semiconductor device includes a first semiconductive region, a second semiconductive region and an isolation structure. The isolation structure is formed between the first semiconductive region and the second semiconductive region and includes an isolation bottom formed beneath the second semiconductive region and an isolation ring with a lower portion connecting the isolation bottom and an upper portion surrounding the second semiconductive region. The isolation ring includes a plurality of insulating regions and a plurality of doped regions formed alternately. The isolation bottom and the plurality of insulating regions have an insulating material. The plurality of doped regions have dopants of a conductivity type complementary to those of the first semiconductive region and the second semiconductive region.

### BACKGROUND

Semiconductor devices are used in a large number of electronic devices, such as computers, cell phones, and others. Semiconductor devices comprise integrated circuits that are formed on semiconductor wafers by depositing many types of thin films of material over the semiconductor wafers, and patterning the thin films of material to form the integrated circuits. Integrated circuits include field-effect transistors (FETs) such as metal oxide semiconductor (MOS) transistors.

One of the goals of the semiconductor industry is to continue shrinking the size and increasing the speed of individual FETs. Silicon on insulator (SOI) devices have been recognized as one of the possible solutions to enable continued scaling. SOI devices offer a number of advantages over bulk devices. For example, SOI devices exhibit very low junction capacitance compared to bulk devices. The source and drain junction capacitances are almost entirely eliminated.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor device, in accordance with some embodiments of the present disclosure.

FIG. 2 illustrates a top view of the semiconductor device shown in FIG. 1, in accordance with some embodiments of the present disclosure.

FIG. 3A illustrates a first cross-sectional side view, which is along line A-A of the semiconductor device shown in FIG. 2, in accordance with some embodiments of the present disclosure.

FIG. 3B illustrates a second cross-sectional side view, which is along line B-B of the semiconductor device shown in FIG. 2, in accordance with some embodiments of the present disclosure.

FIG. 3C illustrates a third cross-sectional side view, which is along line C-C of the semiconductor device shown in FIG. 2, in accordance with some embodiments of the present disclosure.

FIG. 4A illustrates a first cross-sectional side view of the semiconductor device, in accordance with some another embodiments of the present disclosure.

FIG. 4B illustrates a second cross-sectional side view of the semiconductor device, in accordance with some another embodiments of the present disclosure.

FIG. 5A illustrates a first cross-sectional side view of the semiconductor device, in accordance with some alternative embodiments of the present disclosure.

FIG. 5B illustrates a second cross-sectional side view of the semiconductor device, in accordance with some alternative embodiments of the present disclosure.

FIGS. 6 to 15A are top views of the semiconductor device, in accordance with various embodiments of the present disclosure.

FIG. 15B is a partially enlarged view of the circled area shown in FIG. 15A, in accordance with an embodiment of the present disclosure.

FIG. 16A to 16C are partially enlarged top view of the semiconductor device, in accordance with various embodiments of the present disclosure.

FIG. 17 is a flowchart of a method for forming the semiconductor device in accordance with some embodiments.

FIGS. 18A to 18E illustrate various perspective views of forming the semiconductor device in accordance with some embodiments as described in FIG. 17.

FIGS. 19A to 19C illustrate various cross-sectional side views along line B′-B′ of the semiconductor device shown in FIGS. 18A to 18C, respectively, in accordance with some embodiments of the present disclosure.

FIG. 20 illustrates a cross-sectional side views along line A′-A′ of the semiconductor device shown in FIGS. 18D, in accordance with some embodiments of the present disclosure.

FIG. 21 is a flowchart of a method for forming the semiconductor device in accordance with some another embodiments.

FIGS. 22A to 22E illustrate various perspective views of forming the semiconductor device in accordance with some embodiments as described in FIG. 21.

FIGS. 23A and 23B illustrate various cross-sectional side views along line A′-A′ of the semiconductor device shown in FIGS. 22A and 22B, respectively, in accordance with some embodiments of the present disclosure.

FIGS. 24A to 24C illustrate various cross-sectional side views along line B′-B′ of the semiconductor device shown in FIGS. 22C to 22E, respectively, in accordance with some embodiments of the present disclosure.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

A comparative semiconductor-on-insulator (SOI) structure comprises a substrate, an insulator formed on the substrate and a layer of semiconductive material formed on the insulator, so that the insulator isolates the layer of semiconductive material from the substrate. However, such insulator can only provide a single-direction isolation and require high costs. Alternatively, anti-doped implantation may be conducted to provide a full direction junction isolation. However, such junction isolation may bring parasitic capacitance and would reduce device performance. Furthermore, the isolation ability of the junction isolation may be worse than that of the insulator. There is a need to provide a cost effective isolation structure with superior full direction isolation and less parasitic effect.

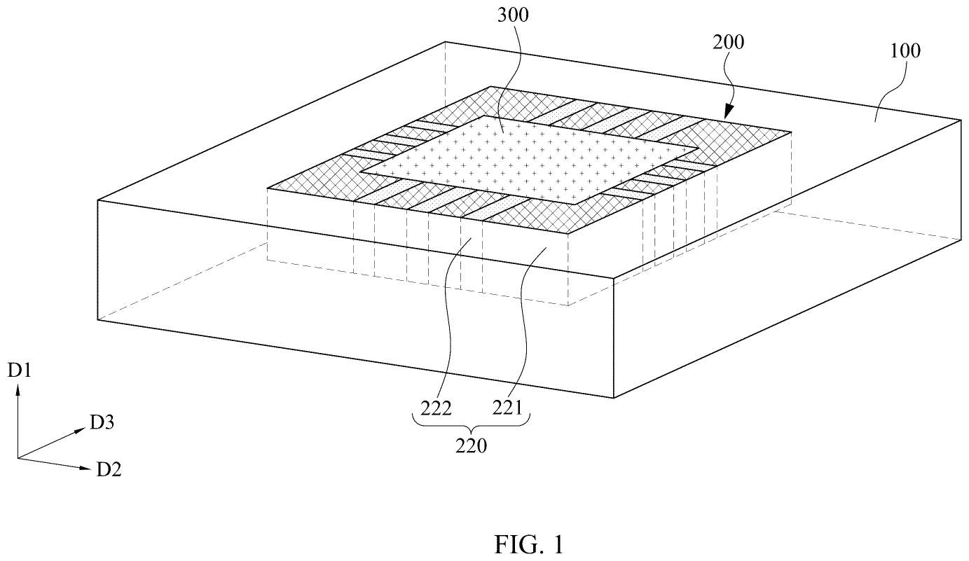

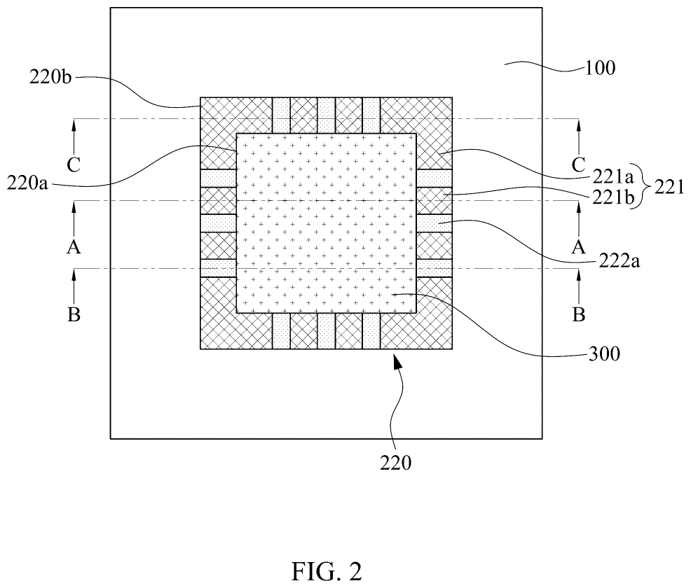

Referring to FIGS. 1 and 2, the semiconductor device includes a first semiconductive region 100, an isolation structure 200 and a second semiconductive region 300 separating from the first semiconductive region 100 through the isolation structure 200.

The first semiconductive region 100 may be formed in the semiconductor device using metal-organic chemical vapor deposition (MOCVD), molecular beam epitaxy (MBE), liquid phase epitaxy (LPE), vapor phase epitaxy (VPE), selective epitaxial growth (SEG), the like, or a combination thereof. In some embodiments, the first semiconductive region 100 comprises SiGe, Ge, GeSn, SiGeSn, or a III-V material. In embodiments wherein the first semiconductive region 100 comprises a III-V material, the first semiconductive region 100 may comprise InAs, AlAs, GaAs, InP, GaN, InGaAs, InAlAs, GaSb, AlSb, AIP, or GaP, as examples. The first semiconductive region 100 may comprise a thickness of about 3 nm to about 30 nm, or about 10 nm to about 20 nm, for example. The first semiconductive region 100 may also comprise other materials and dimensions, and may be formed using other methods.

The isolation structure 200 is formed in the first semiconductive region 100. In some embodiments, the isolation structure 200 has an isolation bottom 210 and an isolation ring 220. A top of the isolation structure 200 may be substantially coplanar with a top of the first semiconductive region 100. The isolation bottom 210 is formed in the first semiconductive region 100 and may comprise oxide (such as SiO, doped SiO and so on), nitride (such as SiN), carbide (such as SiC), low k materials or a combination thereof. For example, the isolation bottom 210 may comprise silicon oxide, doped silicon oxide, silicon carbide, silicon nitride and so on. These are, of course, merely examples and are not intended to be limiting.

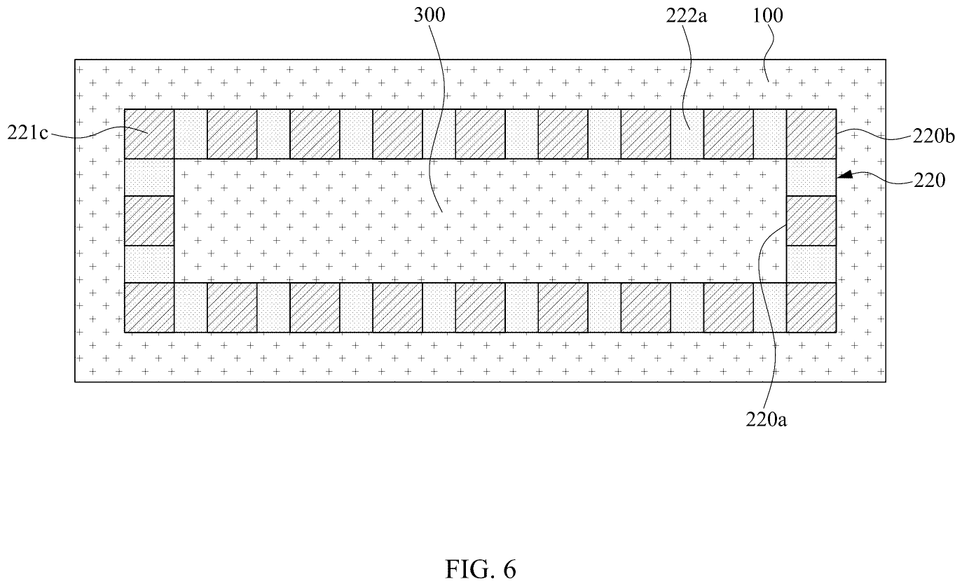

The isolation ring 220 has a lower portion connecting the isolation bottom 210 and an upper portion surrounding the second semiconductive region 300. The isolation ring 220 may be in any shape, such as a rectangular shape (as shown in FIG. 1), a triangular shape, circular shape, or other regular or irregular shapes. These are, of course, merely examples and are not intended to be limiting. The isolation ring 220 comprises a plurality of insulating regions 221 and a plurality of doped regions 222. The plurality of doped regions 222 may be formed separately by the insulating regions 221 as shown in FIG. 2 or may be formed continuously by partially or completely overlapping the insulating regions 221 as shown in FIGS. 6 to 16. The plurality of doped regions 222 connect the isolation bottom 210. In some embodiments, the plurality of doped regions 222 may be formed on the isolation bottom 210. In some alternative embodiments, the plurality of doped regions 222 may be formed in the first semiconductive region 100 and adjacent to the isolation bottom 210. In some alternative embodiments, the plurality of doped regions 222 may be partially formed in the semiconductive region 100 and partially formed on the isolation bottom 210.

A ratio of the plurality of insulating regions 221 to the isolation ring 220 may range from about 10 vol. % to about 90 vol. % according to required process/product window. In some embodiments, the ratio of the plurality of insulating regions 221 to the isolation ring 220 may range from about 20 vol. % to about 80 vol. %. In some embodiments, the ratio of the plurality of insulating regions 221 to the isolation ring 220 may range from about 30 vol. % to about 70 vol. %. As shown in FIGS. 1 and 2, the plurality of insulating regions 221 and the plurality of doped regions 222a may be formed alternately along a second direction D2 and a third direction D3. Alternatively, the plurality of insulating regions 221 and the plurality of doped regions 222a may partially overlap.

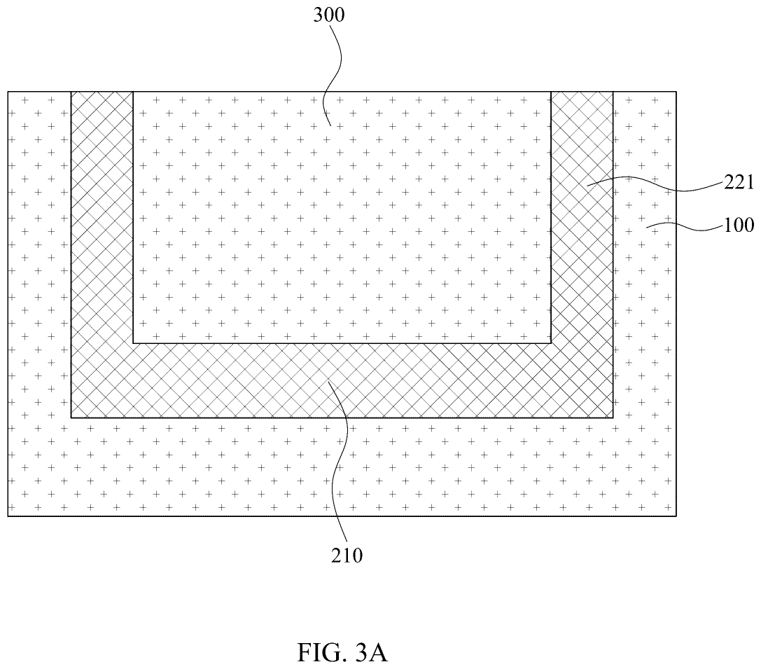

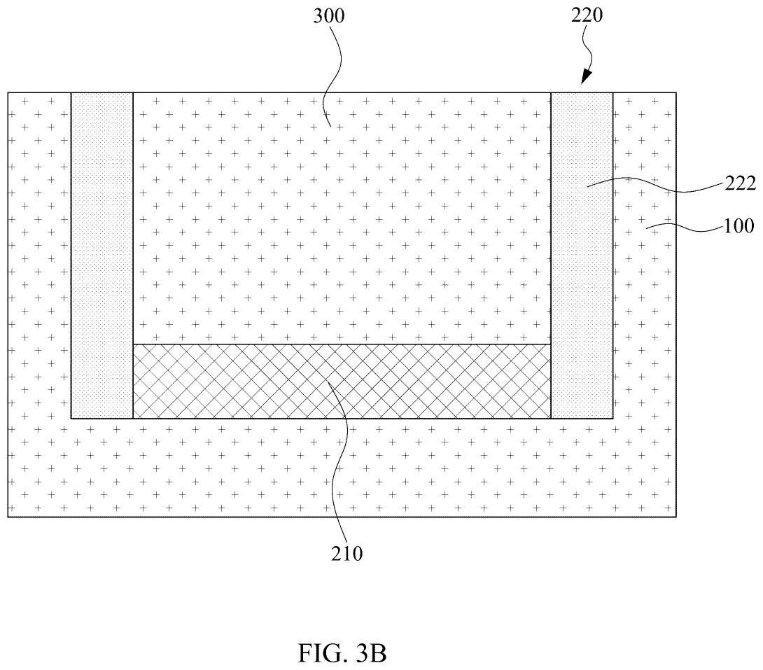

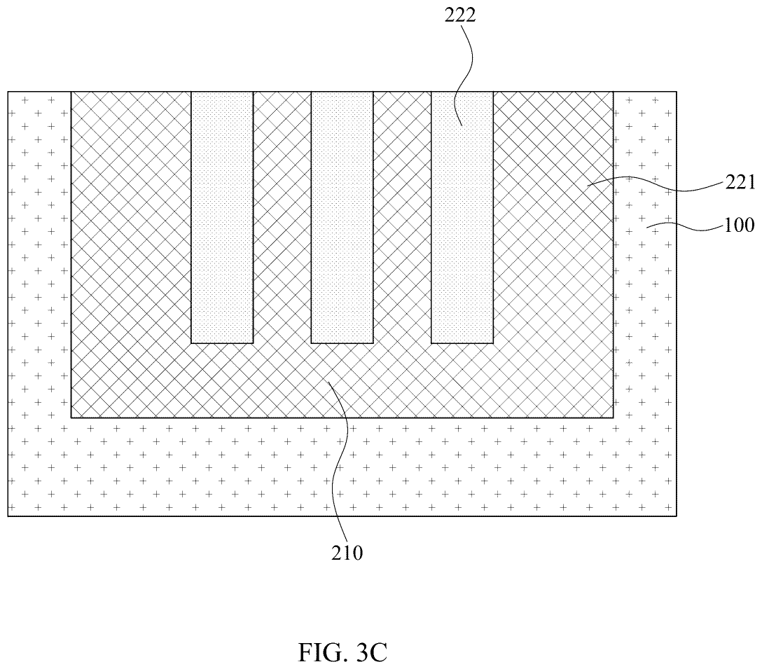

FIG. 3A is a cross-sectional side view along line A-A of the semiconductor device shown in FIG. 2. As shown in FIG. 3A, the plurality of insulating regions 221 are formed on the isolation bottom 210. The plurality of insulating regions 221 may comprise a material substantially identical to or different from the material for forming the isolation bottom 210. The plurality of insulating regions 221 may comprise insulating materials, including but not limited to oxide (such as SiO, doped SiO and so on), nitride (such as SiN), carbide (such as SiC), low k materials or a combination thereof. For example, the plurality of insulating regions 221 may comprise silicon oxide, doped silicon oxide, silicon carbide, silicon nitride and so on. These are, of course, merely examples and are not intended to be limiting. The plurality of insulating regions 221 may have various shapes, including rectangular, circular, and so on.

FIG. 3B is a cross-sectional side view along line B-B of the semiconductor device shown in FIG. 2 and FIG. 3C is a cross-sectional side view along line C-C of the semiconductor device shown in FIG. 1. As shown in FIGS. 3B and 3C, the plurality of doped regions 222a are formed on the isolation bottom 210 and each of the doped regions 222a is formed between two of the plurality of insulating regions 221. The doped regions 222a may have insulating dopants, such as dopants of a conductivity type complementary to those of the first semiconductive region 100 and the second semiconductive region 300, and thus provide insulating effects. For example, when the first semiconductive region 100 and the second semiconductive region 300 are p-type metal oxide semiconductor (PMOS), the doped regions 222a comprises n-type dopants; and when the first semiconductive region 100 and the second semiconductive region 300 are n-type metal oxide semiconductor (NMOS), the doped regions 222a comprise p-type dopants. For example, the p-type dopants may be boron (for example, BF₂), indium, gallium, other p-type dopant, or combinations thereof and the n-type dopants may be phosphorus, arsenic, other n-type dopant, or combinations thereof.

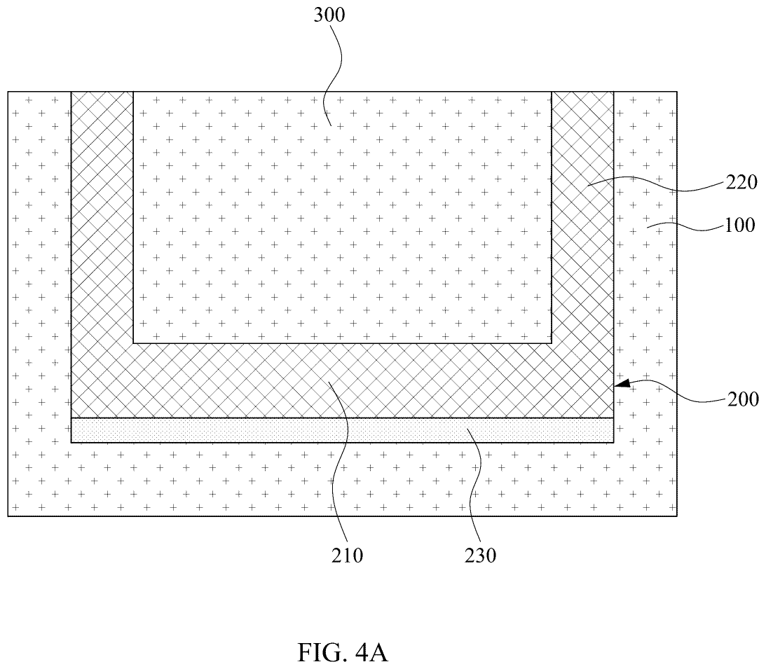

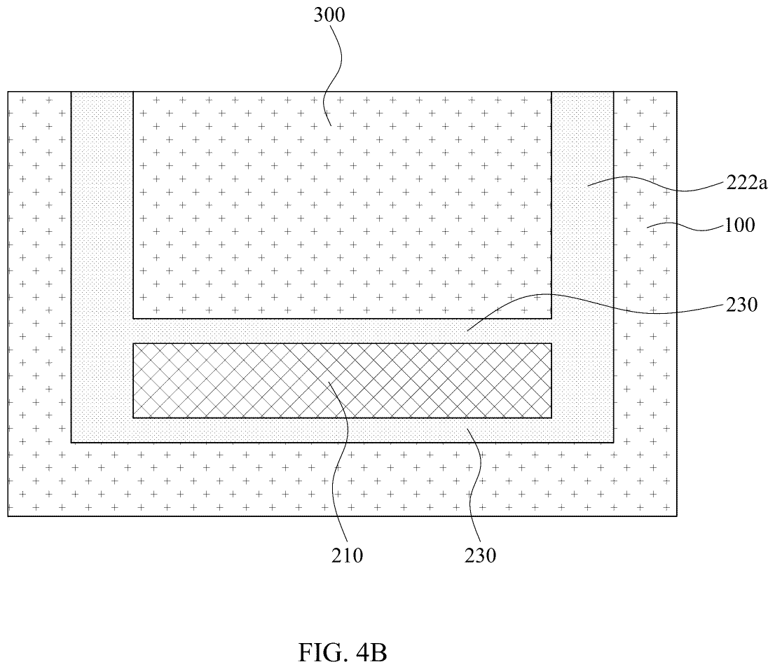

As shown in FIGS. 4A and 4B, in some another embodiments, the isolation ring 220 may further comprise at least one doped layer 230. The doped layer 230 may be formed beneath a lower surface of the isolation bottom 210 and a lower surface of the isolation ring 220 as shown in FIGS. 4A and 4B so the doped layer 230 is sandwiched by the isolation structure 200 and the first semiconductive region 100. In view of FIG. 4B, the doped layer 230 may be formed on an upper surface of the isolation bottom 210 so the doped layer 230 is sandwiched by the isolation bottom 210 and the second semiconductive region 300. The doped layer 230 may have insulating dopants substantially identical to those in the doped regions 222, such as dopants of a conductivity type complementary to those of the first semiconductive region 100 and the second semiconductive region 300.

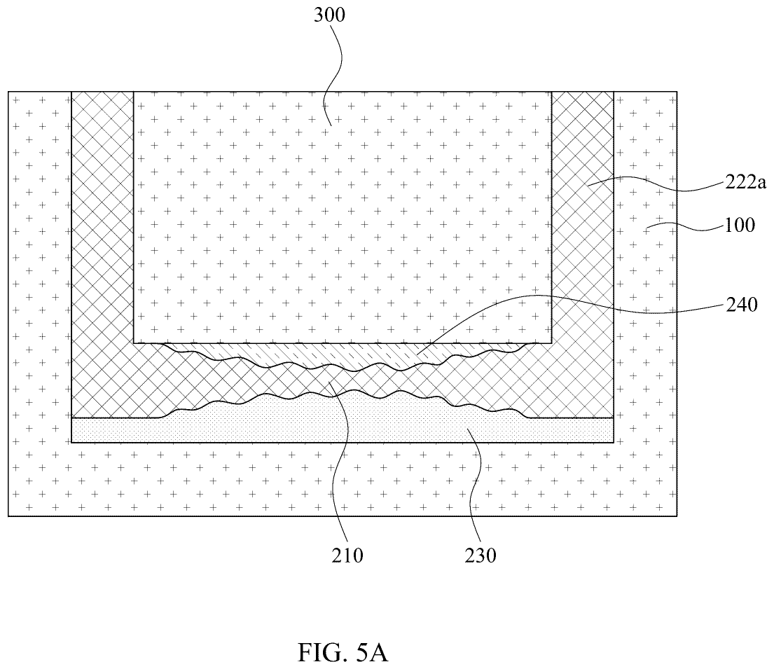

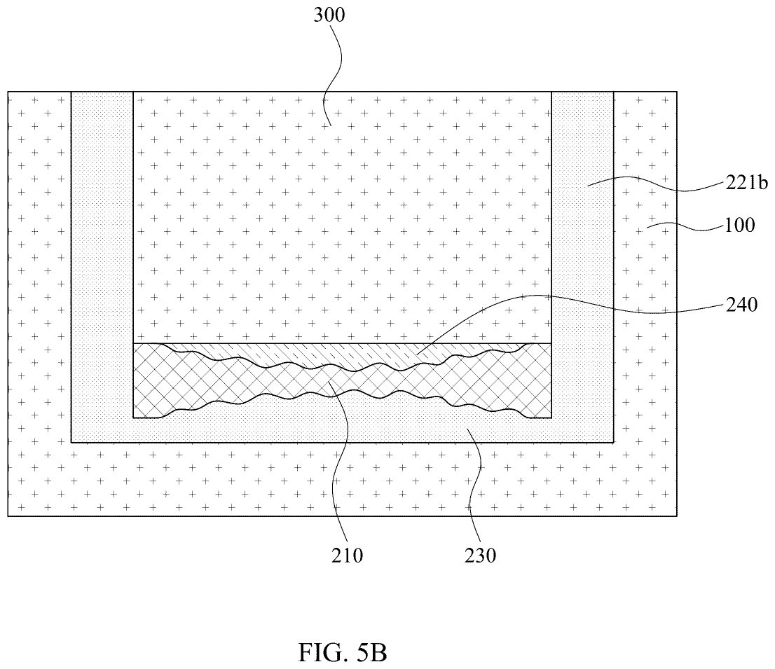

With reference to FIGS. 5A and 5B, in some embodiments, the isolation structure 200 may further comprise at least one embedded doped region 240, which can be formed on the upper surface of the isolation bottom 210 and/or formed beneath the lower surface of the isolation bottom 210. When the first semiconductive region 100 and a second semiconductive region 300 comprise P-type materials, the embedded doped region 240 may comprise highly doped p-type dopants (e.g., P+ dopants) or even heavily doped p-type dopants (e.g., P++ dopants). The p-type dopants may comprise B, Ga, or In implanted to a concentration equal to or greater than from about 10¹⁵ atoms/cm⁻³. In some embodiments, the concentration may range from about 10¹⁵ atoms/cm⁻³ to 10²⁰ atoms/cm⁻³. When the first semiconductive region 100 and a second semiconductive region 300 comprise n-type materials, the embedded doped region 240 may comprise highly doped n-type dopants (e.g., N+ dopants) or even heavily doped n-type dopants (e.g., N++ dopants). The n-type dopants may be phosphorus, arsenic, other n-type dopant, or combinations thereof.

With further reference to FIGS. 4A and 4B, the lower surface of the isolation bottom 210 may be a plane and the upper surface of the isolation bottom 210 may be a plane, so that the lower surface of the isolation bottom 210 may be parallel to the upper surface of the isolation bottom 210 and a thickness of the isolation bottom 210 can be consistent from a central region to a peripheral region on which the isolation ring 220 is formed. Alternatively, as shown in FIGS. 5A and 5B, the lower surface of the isolation bottom 210 may be an irregular surface and the upper surface of the isolation bottom 210 may also be an irregular surface, so that the thickness of the isolation bottom 210 is inconsistent from a central region to the peripheral region. For example, the thickness of the isolation bottom 210 may be gradually decreased from the peripheral region of the isolation bottom 210 to the central region of the isolation bottom 210.

The second semiconductive region 300 is located on the isolation bottom 210 of the isolation structure 200 and is surrounded by the isolation ring 220. The second semiconductive region 300 may have a material substantially identical to the material of the first semiconductive region 100. A top of the second semiconductive region 300 is substantially coplanar with the top of the first semiconductive region 100 and the top of the isolation structure 200.

In some embodiments, with reference to FIG. 2, the isolation ring 220 may have a rectangular top view and has four L-shape insulating regions 221a, a plurality of rectangular insulating regions 221b and a plurality of rectangular doped regions 222a formed between the L-shape insulating regions 221a and the rectangular insulating regions 221b and between the rectangular insulating regions 221b. Inner surfaces of the L-shape insulating regions 221a and the rectangular insulating regions 221b can be aligned with inner surfaces of the rectangular doped regions 222a so that an inner surface 220a of the isolation ring 220 may form a flat rectangular edge. Therefore, the second semiconductive region 300 is a tetrahedron. Outer surfaces of the L-shape insulating regions 221a and the rectangular insulating regions 221b can be aligned with inner surfaces of the rectangular doped regions 222a so that an outer surface 220b of the isolation ring 220 may form a flat rectangular edge.

In some another embodiments, with reference to FIG. 6, the isolation ring 220 may have a rectangular top view and has a plurality of rectangular doped insulating regions 221c and a plurality of rectangular doped regions 222a, which are formed alternately. The rectangular doped insulating regions 221c may comprise insulating materials and the dopants, which are substantially identical to the dopants doped in the rectangular doped regions 222a. In some embodiments, a top surface of the rectangular doped insulating region 221c may be equal to or similar to a top surface of the rectangular doped region 222a. Inner surfaces of the rectangular doped insulating regions 221c can be aligned with inner surfaces of the rectangular doped regions 222a so that an inner surface 220a of the isolation ring 220 may form a flat rectangular edge. Therefore, the second semiconductive region 300 is a tetrahedron. Outer surfaces of the rectangular doped insulating regions 221c can be aligned with inner surfaces of the rectangular doped regions 222a so that an outer surface 220b of the isolation ring 220 may form a flat rectangular edge.

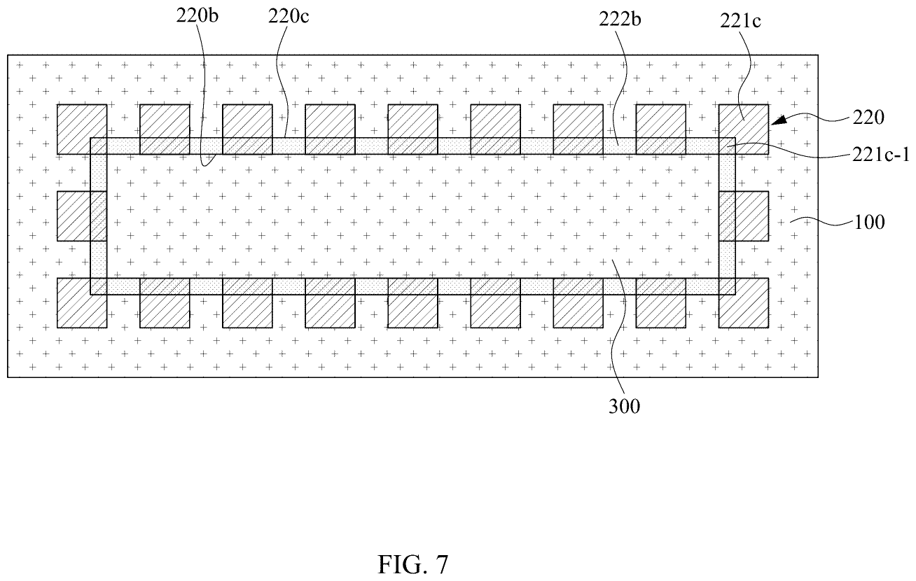

In some another embodiments, with reference to FIG. 7, the isolation ring 220 has a plurality of rectangular doped insulating regions 221c and a plurality of rectangular doped regions 222b, which are formed alternately. Each of the rectangular doped insulating regions 221c may comprise insulating materials and a doped portion 221c-1 formed along an inner edge or in a corner of the rectangular doped insulating region 221c and having dopants substantially identical to the dopants doped in the rectangular doped regions 222b. The doped portions 221c-1 of the rectangular doped insulating regions 221c and the rectangular doped regions 222b are formed in contact with each other. In some embodiments, a top surface of the rectangular doped insulating region 221c may be larger than a top surface of the rectangular doped region 222b. Inner surfaces of the rectangular doped insulating regions 221c can be aligned with inner surfaces of the rectangular doped regions 222b so that an inner surface 220a of the isolation ring 220 may form a flat rectangular edge. Therefore, the second semiconductive region 300 is a tetrahedron. An outer surface 220c of the isolation ring 220 may be a serrated surface.

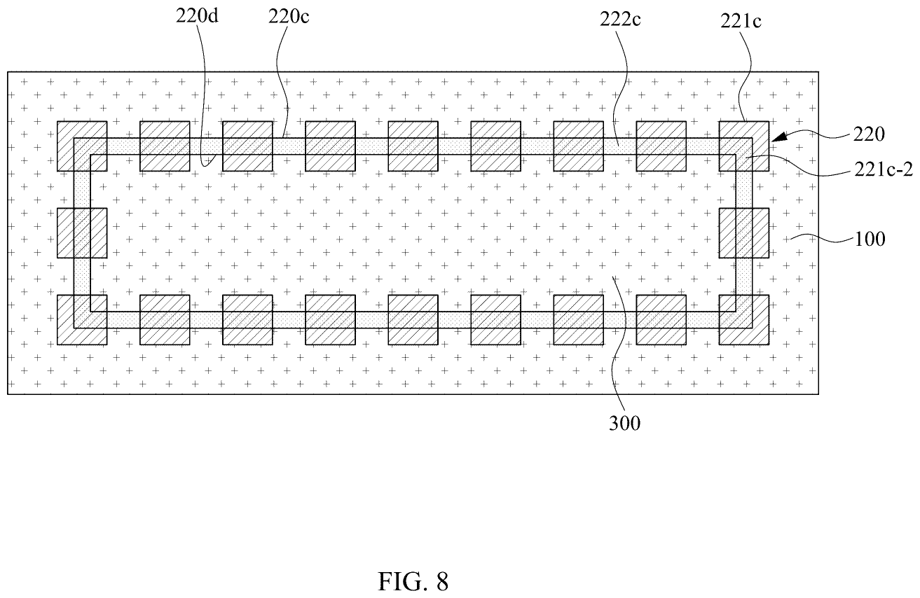

In some another embodiments, with reference to FIG. 8, the isolation ring 220 has a plurality of rectangular doped insulating regions 221c and a plurality of rectangular doped regions 222c, which are formed alternately. Each of the rectangular doped insulating regions 221c may comprise insulating materials and a doped portion 221c-2 formed in a middle portion of the doped insulating region 221c and having dopants substantially identical to the dopants doped in the rectangular doped regions 222c. The doped portions 221c-2 of the rectangular doped insulating regions 221c and the rectangular doped regions 222c are in contact with each other. In some embodiments, a top surface of the rectangular doped insulating region 221c may be larger than a top surface of the rectangular doped region 222c. Inner surface 220d of the isolation ring 220 may be a serrated surface and an outer surface 220c of the isolation ring 220 may be a serrated surface.

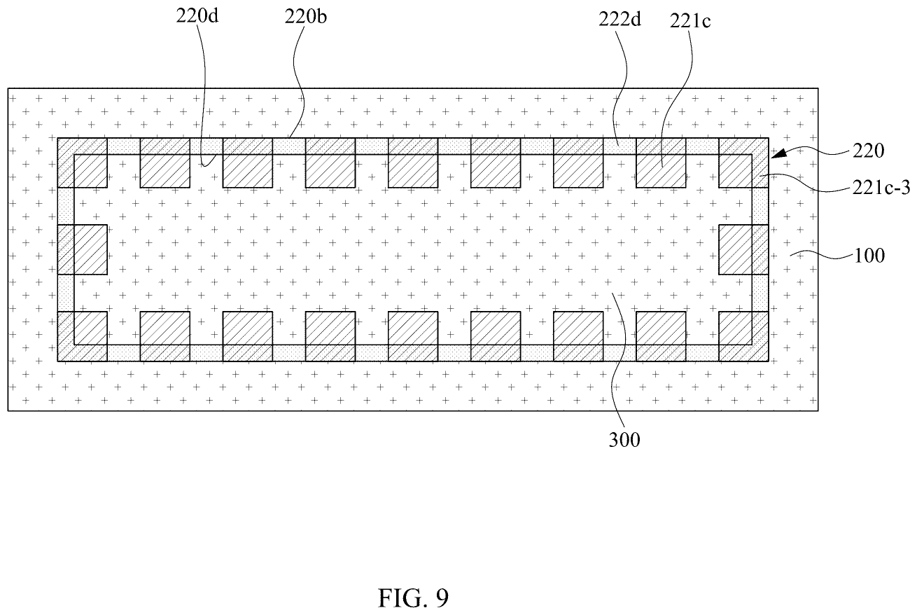

In some another embodiments, with reference to FIG. 9, the isolation ring 220 has a plurality of rectangular doped insulating regions 221c and a plurality of rectangular doped regions 222d, which are formed alternately. Each of the rectangular doped insulating regions 221c may comprise insulating materials and a doped portion 221c-3 formed along an outer edge or in a corner of the rectangular doped insulating region 221c and having dopants substantially identical to the dopants doped in the rectangular doped regions 222d. The doped portions 221c-3 of the rectangular doped insulating regions 221c and the rectangular doped regions 222d are in contact with each other. In some embodiments, a top surface of the rectangular doped insulating region 221c may be larger than a top surface of the rectangular doped region 222d. Outer surfaces of the rectangular doped insulating regions 221c can be aligned with outer surfaces of the rectangular doped regions 222d so that the outer surface 220b of the isolation ring 220 may form a flat rectangular edge. An inner surface 220d of the isolation ring 220 may be a serrated surface.

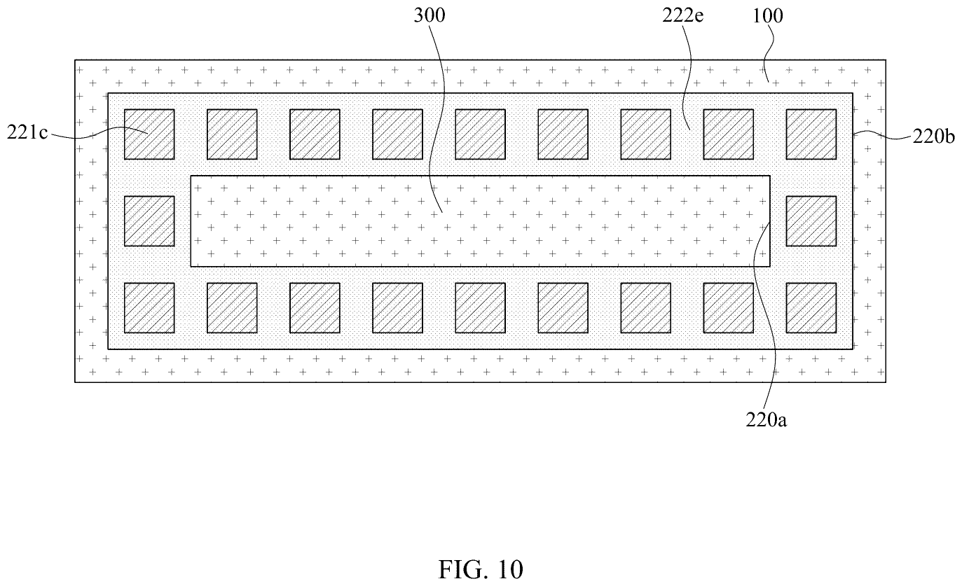

In some alternative embodiments, with reference to FIG. 10, the isolation ring 220 may have a rectangular top view and has a doped ring 222e and a plurality of insulating regions 221c formed in the doped ring 222e at regular or irregular intervals. The insulating regions 221c may be completely covered by the doped ring 222e. An inner surface of the doped ring 222c serves as an inner surface 220a of the isolation ring 220, which is substantially flat; and an outer surface of the doped ring 222e serves as an outer surface 220b of the isolation ring 220, which is substantially flat. There is an interval between an inner surface of each of the insulating regions 221c and the inner surface of the doped ring 222e. There is an interval between an outer surface of each of the insulating regions 221c and the inner surface of the doped ring 222c.

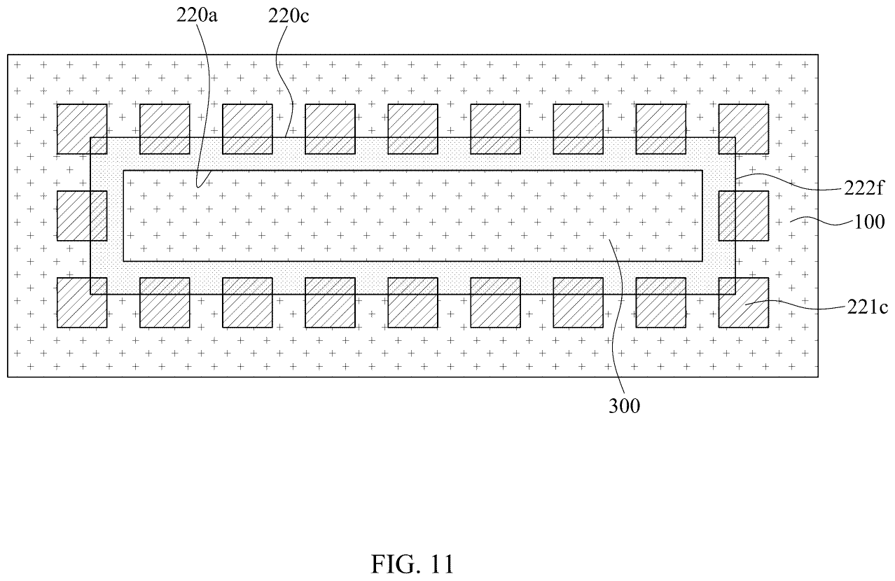

In some alternative embodiments, with reference to FIG. 11, the isolation ring 220 has a doped ring 222f and a plurality of insulating regions 221c formed in the doped ring 222f at regular or irregular intervals. The insulating regions 221c may be partially covered by the doped ring 222c. In this embodiment as shown in FIG. 11, inner surfaces of the insulating regions 221c are covered by the doped ring 222e and there is an interval between an inner surface of each of the insulating regions 221c and the inner surface of the doped ring 222f. An inner surface of the doped ring 222f serves as an inner surface 220a of the isolation ring 220, which is substantially flat; and an outer surface 220c of the isolation ring 220 may be a serrated surface.

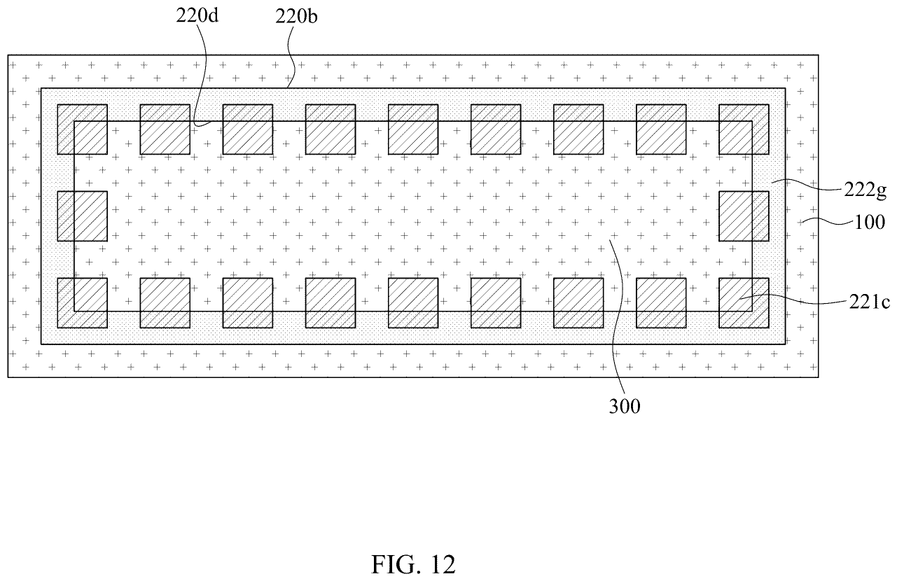

In some alternative embodiments, with reference to FIG. 12, the isolation ring 220 has a doped ring 222g and a plurality of insulating regions 221c formed in the doped ring 222g at regular or irregular intervals. The insulating regions 221c may be partially covered by the doped ring 222g. In this embodiment as shown in FIG. 12, outer surfaces of the insulating regions 221c are covered by the doped ring 222g and there is an interval between an outer surface of each of the insulating regions 221c and the outer surface of the doped ring 222f. An outer surface of the doped ring 222g serves as an outer surface 220b of the isolation ring 220, which is substantially flat; and an inner surface 220d of the isolation ring 220 may be a serrated surface.

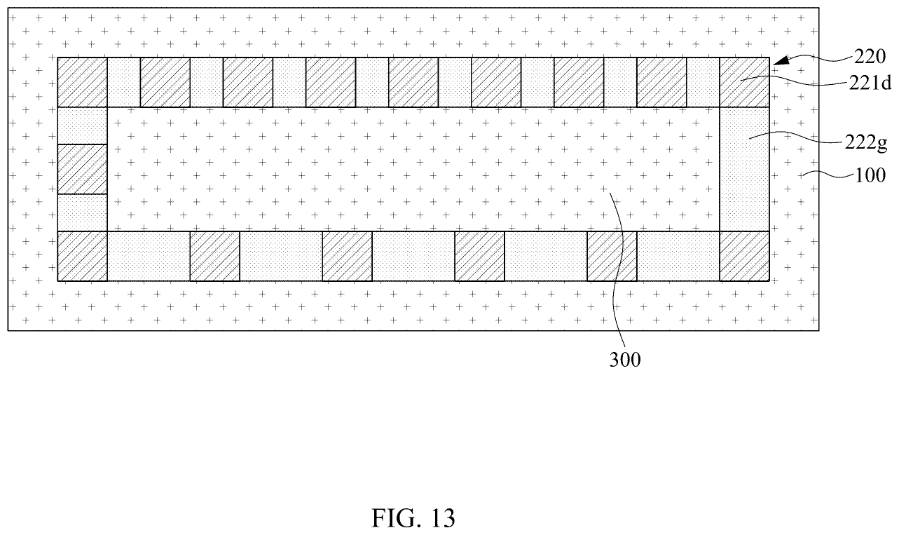

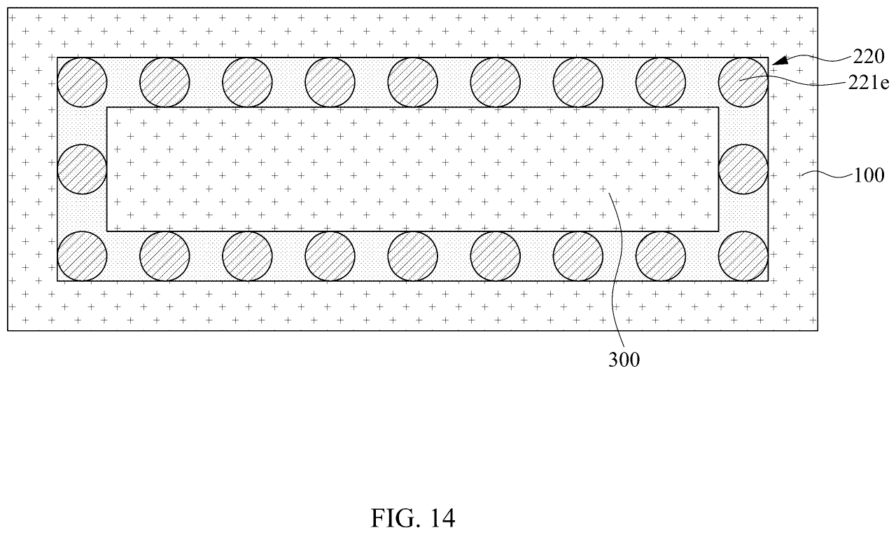

In some embodiments with reference to FIGS. 6 to 12, the plurality of insulating regions 221c may be formed at regular intervals. Further, each of the insulating region 221c may be a tetragon. In some embodiments with reference to FIG. 13, the plurality of insulating regions 221d may be tetrahedron formed at irregular intervals. Further, each of the plurality of insulating regions 221e may be a cylinder as shown in FIG. 14.

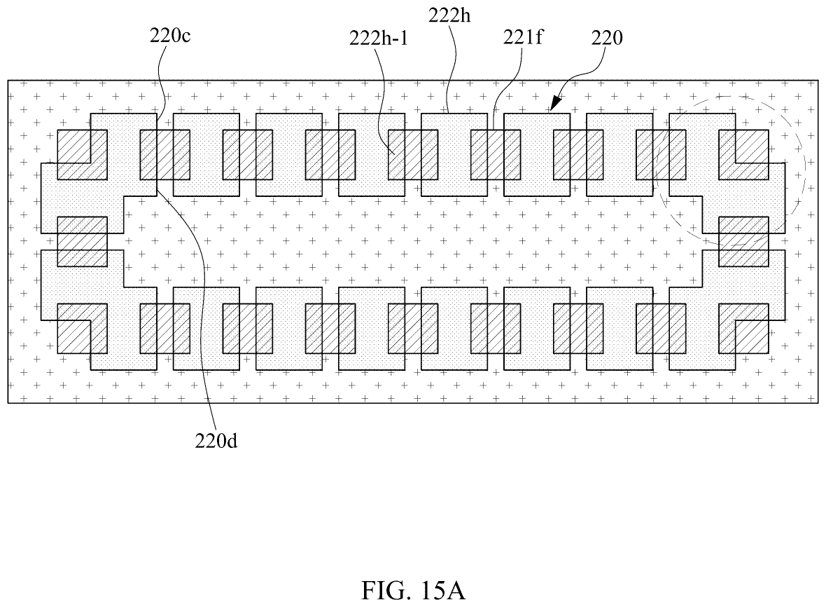

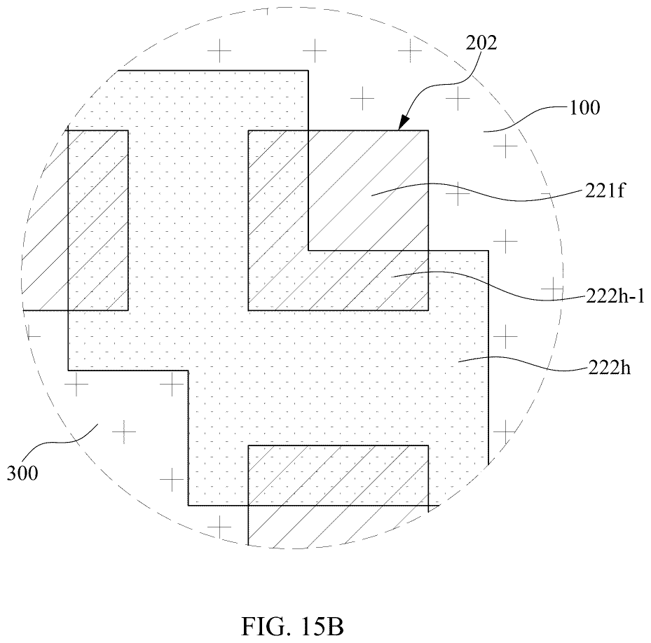

In some alternative embodiments, with reference to FIG. 15A, the isolation ring 220 has a plurality of insulating regions 221f and a plurality of doped regions 222h, which may partially overlap to form a plurality of overlapping regions 222h-1. As shown in FIG. 15B, the doped regions 222h may overlap at corners of the isolation ring 220 while the other doped regions 222h are formed separately from each other. In some embodiments, a top surface of the insulating regions 221f may be larger than a top surface of the doped region 222h. The doped region 222h may have an outer surface expanding toward the first semiconductive region 100 and an inner surface expanding toward the second semiconductive region 300. Inner surface 220d of the isolation ring 220 may be a serrated surface and an outer surface 220c of the isolation ring 220 may be a serrated surface.

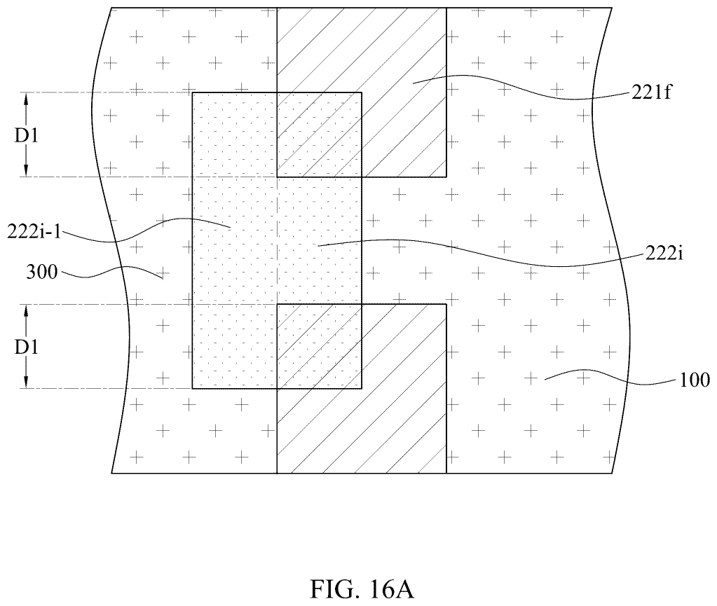

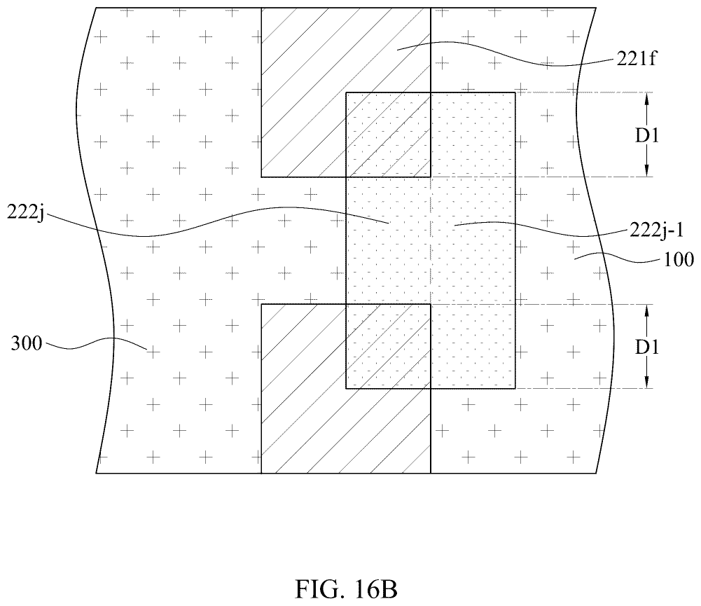

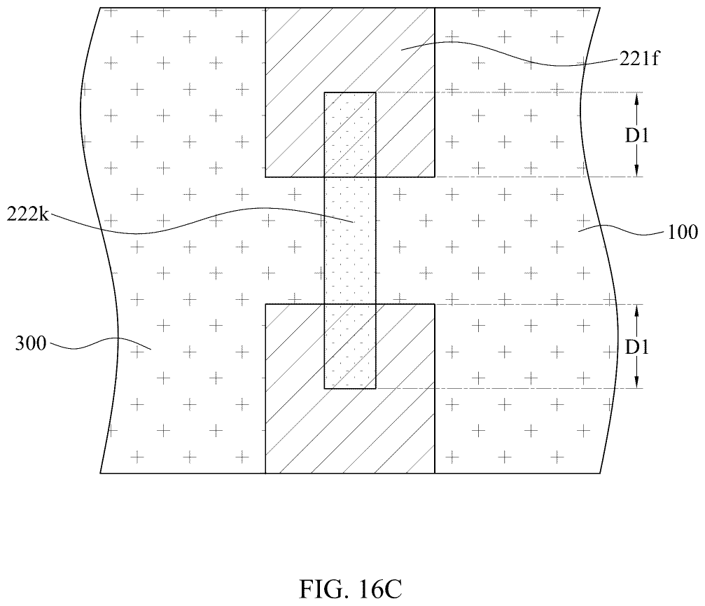

As shown in FIGS. 16A to 16C, an relative position of each of the doped region 222i and each of the insulating regions 221f may be various as long as the doped regions 222i and the insulating regions 221f form the isolation ring 220 to separate the first semiconductive region 100 from the second semiconductive region 300. As shown in FIG. 16A, the doped region 222i has an inner surface expanding toward the first semiconductive region 100 to form an inner portion 222i-1 and an outer surface retracted toward the first semiconductive region 100. As shown in FIG. 16B, the doped region 222j has an outer surface expanding toward the second semiconductive region 300 to form an outer portion 222j-1 and an inner surface retracted toward the second semiconductive region 300. As shown in FIG. 16C, the doped region 222k has an inner surface retracted toward the first semiconductive region 100 and an outer surface retracted toward the second semiconductive region 300.

As shown in FIGS. 16A to 16C, each doped region 222i, 222j and 222k extends from an interval between two insulating regions 221f to the two insulating regions 221f. The doped region 222i, 222j and 222k extends into one adjacent insulating region 22f to a distance D1, which may range from about 10 nm to about 1 μm. In some embodiments, the distance D1 may range from about 50 nm to about 800 nm. In some embodiments, the distance D1 may range from about 100 nm to about 600 nm.

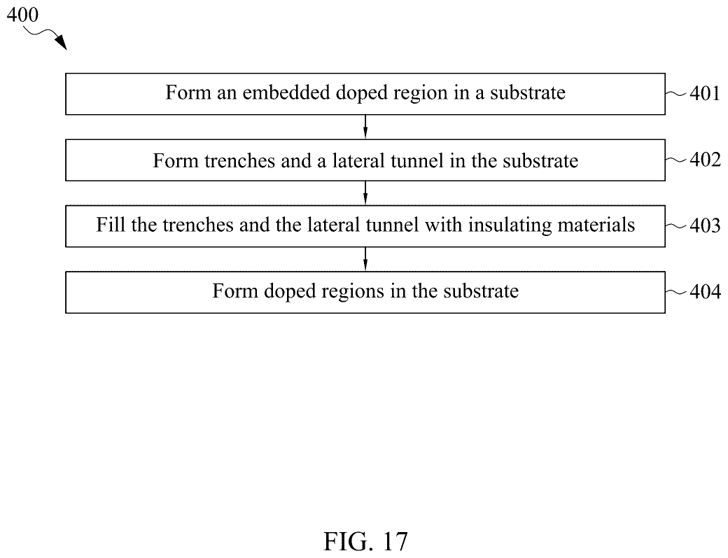

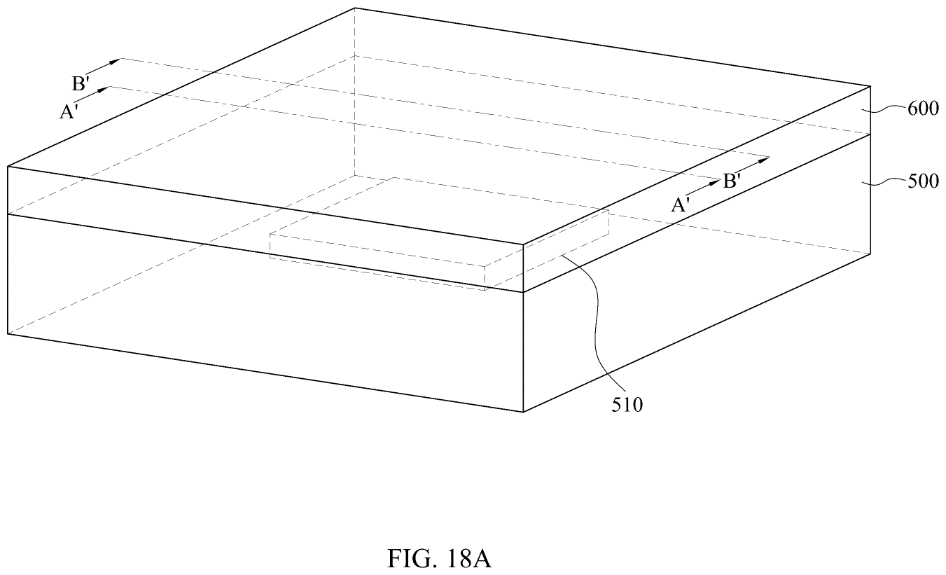

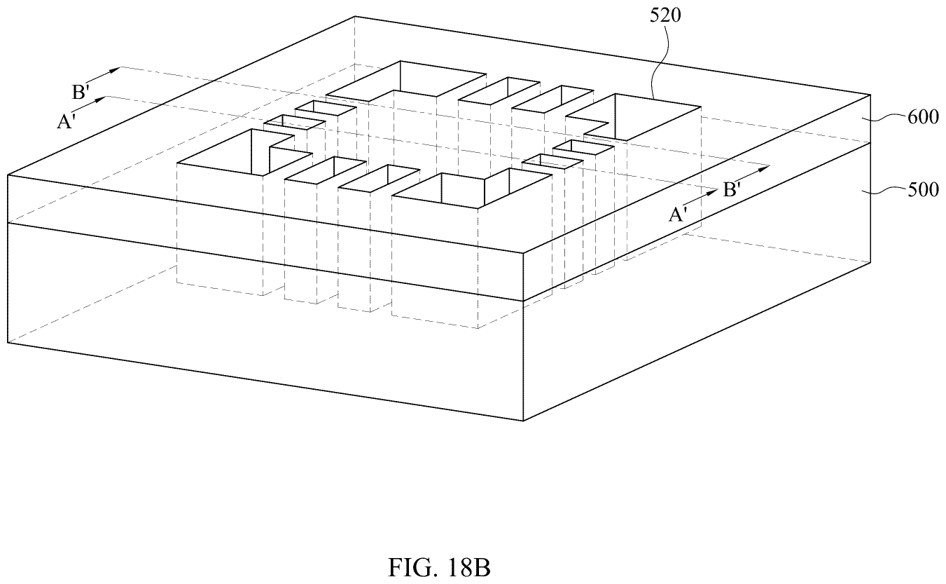

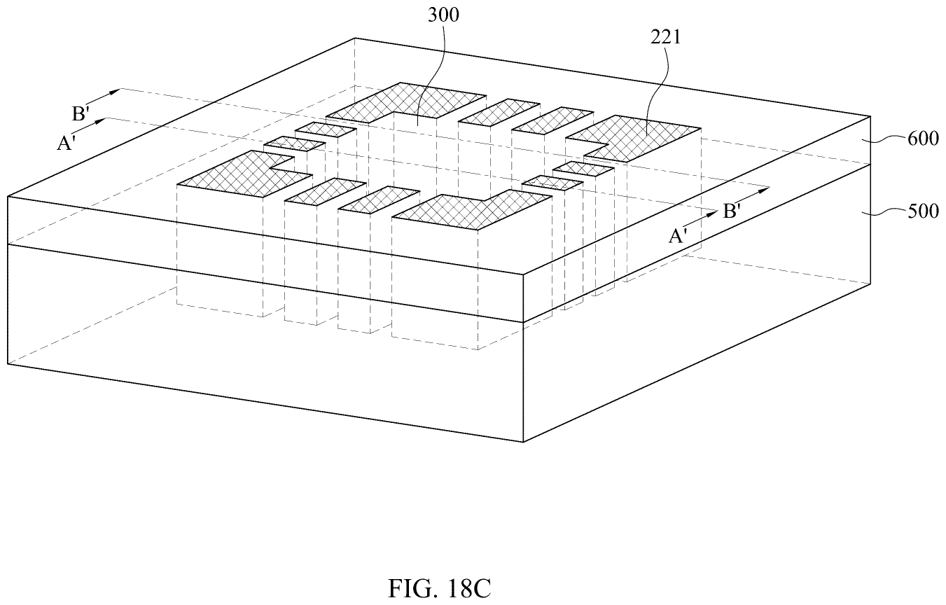

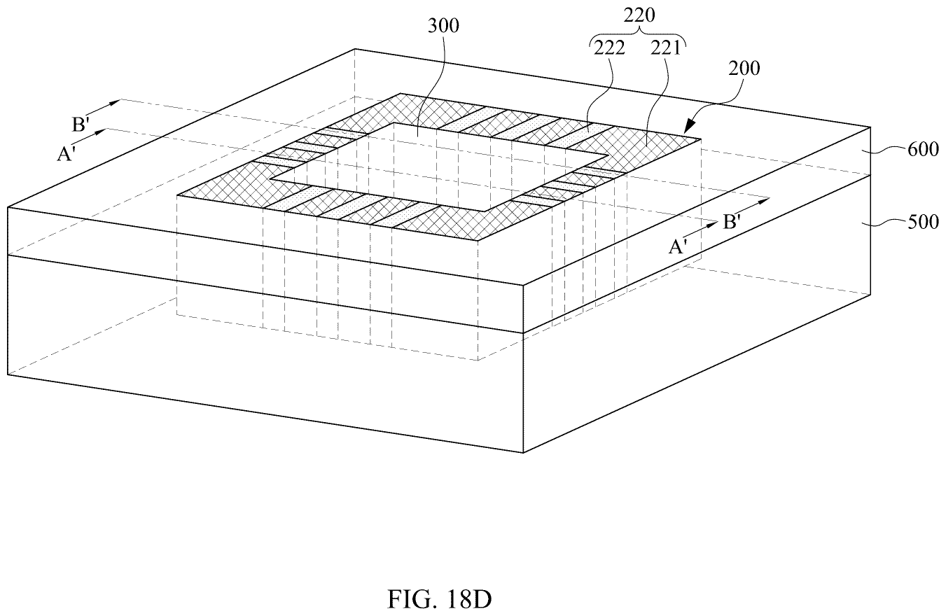

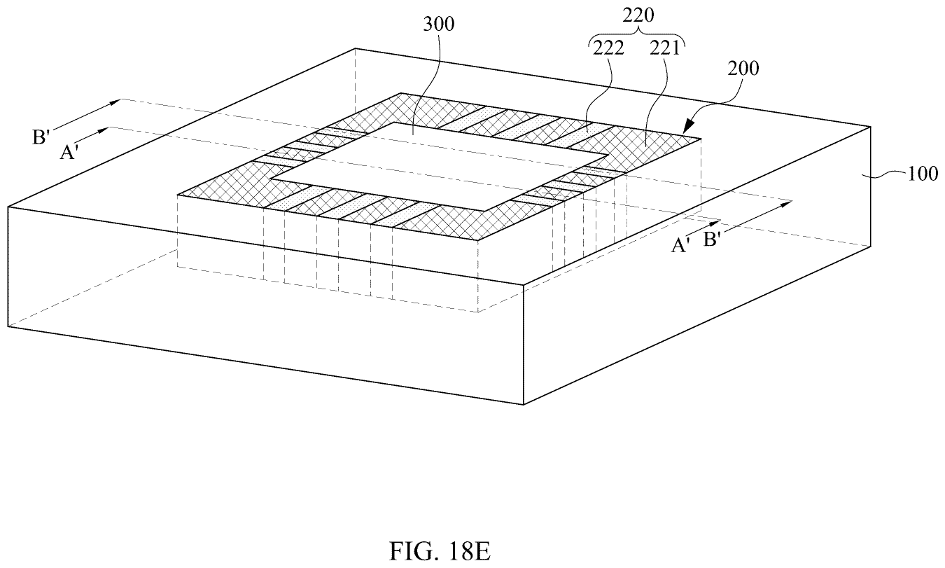

FIG. 17 is a flowchart representing a method 400 for forming a semiconductor device according to various aspects of the present disclosure. In some embodiments, the method 400 for forming the semiconductor device includes a number of operations (401, 402, 403 and 404). The method 400 for forming the semiconductor device will be further described according to one or more embodiments. It should be noted that the operations of the method 400 may be rearranged or otherwise modified within the scope of the various aspects. It should further be noted that additional processes may be provided before, during, and after the method 400, and that some other processes may be only briefly described herein. FIGS. 18A to 18E are diagrammatic perspective views illustrating various stages in the method 400 for forming the connecting structure according to aspects of one or more embodiments of the present disclosure.

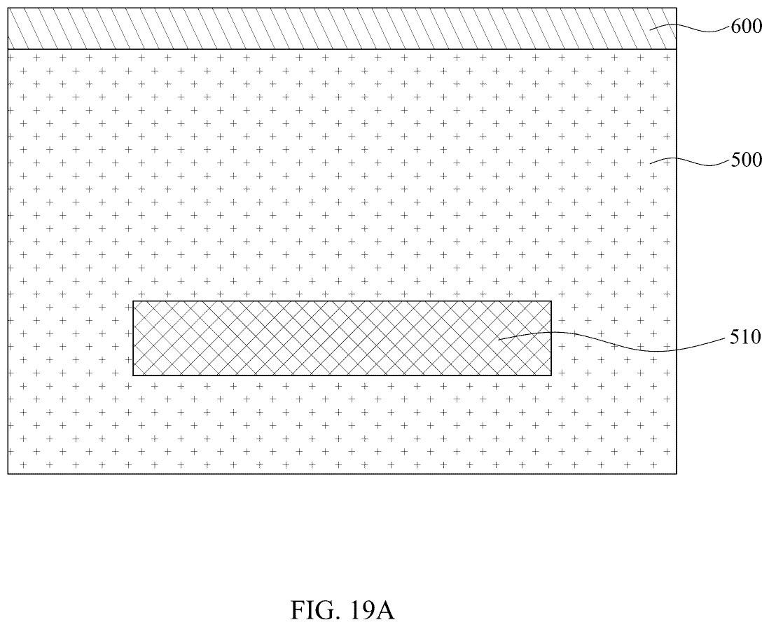

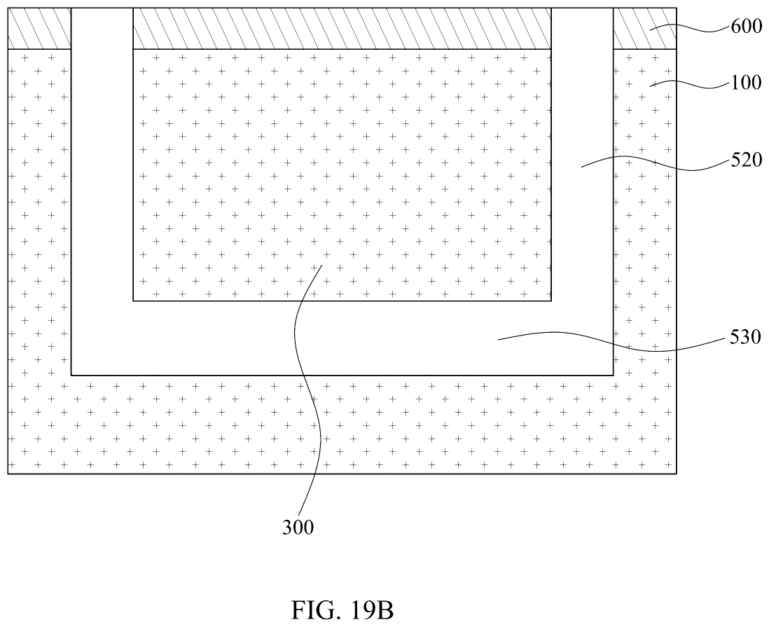

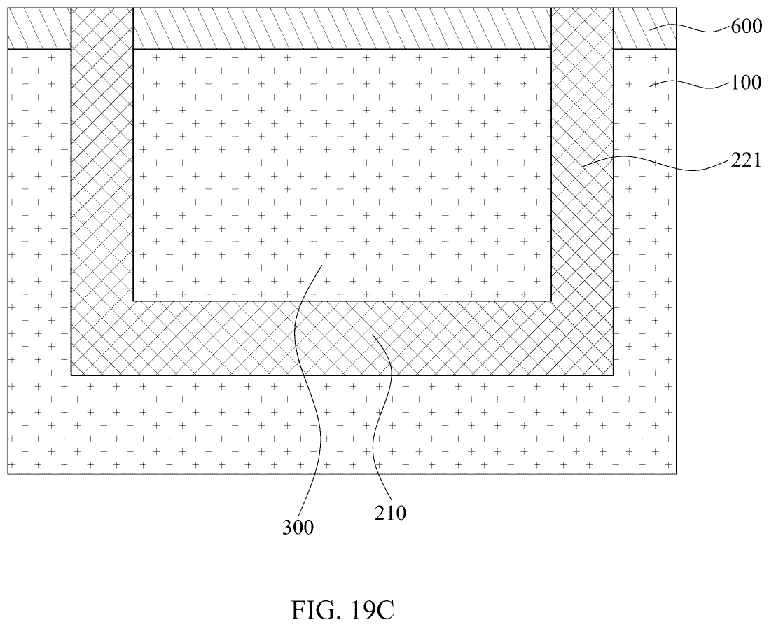

With reference to FIGS. 18A and 19A, the method 400 begins at operation 401 where an embedded doped region 510 is formed in a substrate 500 covered with a sacrificial layer 600. At operation 401, the substrate 500 is provided and received, which may be an N-type substrate or a P-type substrate; then, the sacrificial layer 600 is formed over the substrate 500 before forming the embedded doped region 510 through an implantation process. The sacrificial layer 600 may comprise nitride, silicon oxide or the like, which is used to protect the substrate 500 against any damages (such as crystal damage) generated due to the following implantation processes, so as to ensure high device performance. In some embodiments, the thickness of the sacrificial layer 600 may be from about 40 Å to about 80 Å, but the disclosure is not limited thereto. In some comparative approaches, when the thickness of the sacrificial layer 600 is less than 40 Å, it would not be thick enough to protect the substrate 500. In other comparative approaches, when the thickness of the sacrificial layer 600 is greater than 80 Å, it would be too thick to block the following implantation.

According to some embodiments, the embedded doped region 510 is formed in the substrate 500 at a predetermined depth from a top of the substrate 500 through a vertical implantation or a tilt implantation. The embedded doped region 510 formed by doping a predetermined area of the substrate 500 with materials that have a high etching selectivity in respect to the substrate 500. For example, when the substrate 500 is a p-type substrate, the embedded doped region 510 may comprise highly doped p-type dopants (e.g., P+ dopants) or even heavily doped p-type dopants (e.g., P++ dopants). The p-type dopants may comprise B, Ga, or In implanted to a concentration equal to or greater than from about 10¹⁵ atoms/cm⁻³. In some embodiments, the concentration may range from about 10¹⁵ atoms/cm⁻³ to 10²⁰ atoms/cm⁻³. When the substrate 500 is an n-type substrate, the embedded doped region 510 may comprise highly doped n-type dopants (e.g., N+ dopants) or even heavily doped n-type dopants (e.g., N++ dopants). The n-type dopants may be phosphorus, arsenic, other n-type dopant, or combinations thereof. The ion implantation energy, dosage, and temperature of the substrate 500 used during the implantation processes may be designed to control the penetration depth of the dopants in the substrate 500, so that the embedded doped region 510 can be formed at a predetermined depth in the substrate 500.

As shown in FIGS. 18B and 19B, the method 400 continues with operation 402 where a plurality of trenches 520 are formed at intervals by etching the substrate 500 from the top of the substrate 500 downwardly to a depth aligned with a bottom of the embedded doped region 510 to surround the embedded doped region 510; and laterally etching the embedded doped region 510 through the trenches 520 to form a lateral tunnel 530 as shown in FIG. 19B, which communicate the plurality of trenches 520. In some embodiments, the bottom of the embedded doped region 510 may be in the embedded doped region 510, abut the embedded doped region 510 or partially overlap the embedded doped region 510. In some embodiments, the plurality of trenches 520 are formed using a dry etch process, a wet etch process, or a suitable process; and the lateral tunnel 530 is formed using a dry etch process, a wet etch process, or a suitable process. For example, the plurality of trenches 520 are formed using a dry etch process and the lateral tunnel 530 is formed using a wet etch process. Since the embedded doped region 510 comprises materials with a high etching selectivity in respect to the substrate 500, the formation of the lateral tunnel 530 can be formed in the embedded doped region 510. An example dry etch may use a fluorine-containing precursor (for example, CF₄, SF₆, NF₃, CH₂F₂, CHF₃, and/or C₂F₆), an oxygen-containing precursor, a chlorine-containing precursor (for example, Cl₂, CHCl₃, CCl₄, and/or BCl₃), a bromine-containing precursor (for example, HBr and/or CHBR₃), an iodine-containing precursor, other suitable precursor (which can be used to generate an etchant gas and/or etching plasma), or combinations thereof. An example of a wet etch process implements an etching solution that includes tetramethylammonium hydroxide (TMAH), NH₄OH, H₂O₂, H₂SO₄, HF, HCl, other suitable wet etching constituent, or combinations thereof.

The lateral etching may be even or uneven depending on the dimension of the embedded doped region 510, so a thickness of the lateral tunnel 530 may be consistent or inconsistent. For example, a thickness of the lateral tunnel 530 may be gradually decreased from an area near the trenches 520 to a central area away from the trenches 520.

At operation 403, with reference to FIGS. 18C and 19C, the lateral tunnel 530 is filled with insulating materials to form an isolation bottom 210 and the trenches 520 are filled with insulating materials to form insulating regions 221. The insulating materials include but not limited to oxide (such as SiO, doped SiO and so on), nitride (such as SiN), carbide (such as SiC), low k materials or a combination thereof. In some embodiments, the insulating materials may comprise silicon oxide, doped silicon oxide, silicon carbide, silicon nitride and so on. These are, of course, merely examples and are not intended to be limiting.

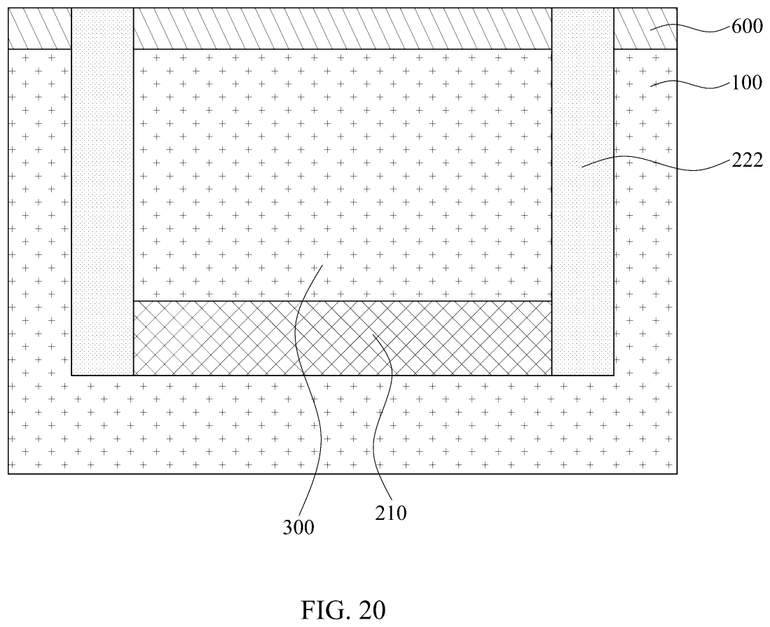

At operation 404, with reference to FIGS. 18D and 20, a plurality of doped regions 222 can be formed between the insulating regions 221 by implanting intervals between the insulating regions 221 to form an isolation ring 220, so that the substrate 500 is divided into a first semiconductive region 100 and a second semiconductive region 300 by the isolation structure 200. Therefore, the first semiconductive region 100 is insulated from the second semiconductive region 300 through the isolation structure 200 including the isolation bottom 210 and the isolation ring 220. The doped regions 222 may have insulating dopants, such as dopants of a conductivity type complementary to those of the first semiconductive region 100 and the second semiconductive region 300, and thus provide insulating effects. The plurality of doped regions 222 may be formed separately by the insulating regions 221 as shown in FIG. 2 or may be formed continuously by partially or completely overlapping the insulating regions 221 as shown in FIGS. 6 to 16.

In addition, a complementary-type implantation may be performed toward the isolation bottom 210 to form at least one doped layer 230 beneath the isolation bottom 210 and/or on the isolation bottom 210 as shown in FIGS. 4A, 4B, 5A and 5B to ensure sufficient isolation effect.

Before conducting following procedures, the sacrificial layer 600 can be removed as shown in FIG. 18E to expose a top of the first semiconductive region 100, a top of the second semiconductive region 300 and a top of the isolation ring 220.

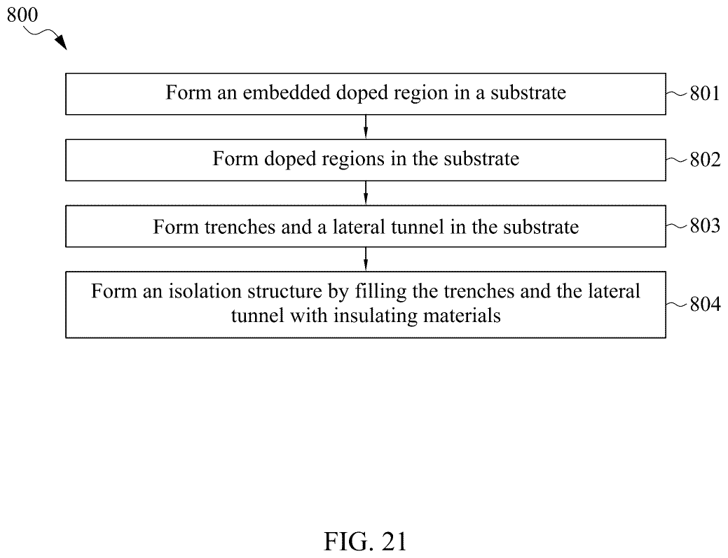

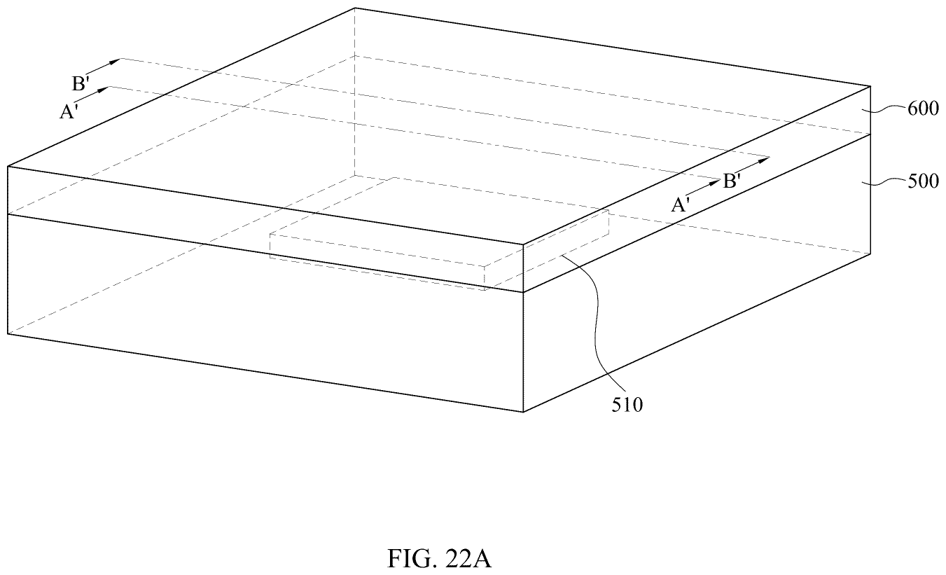

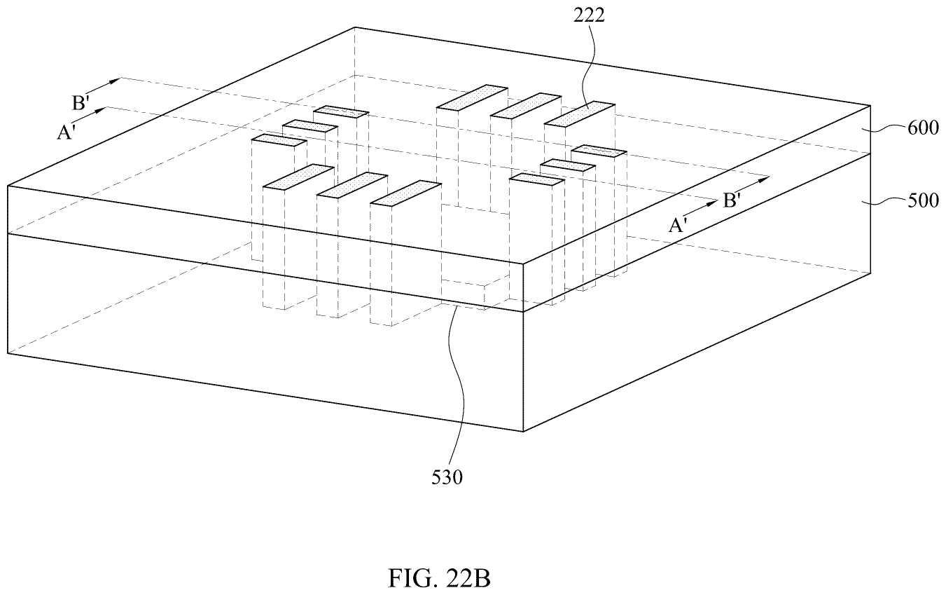

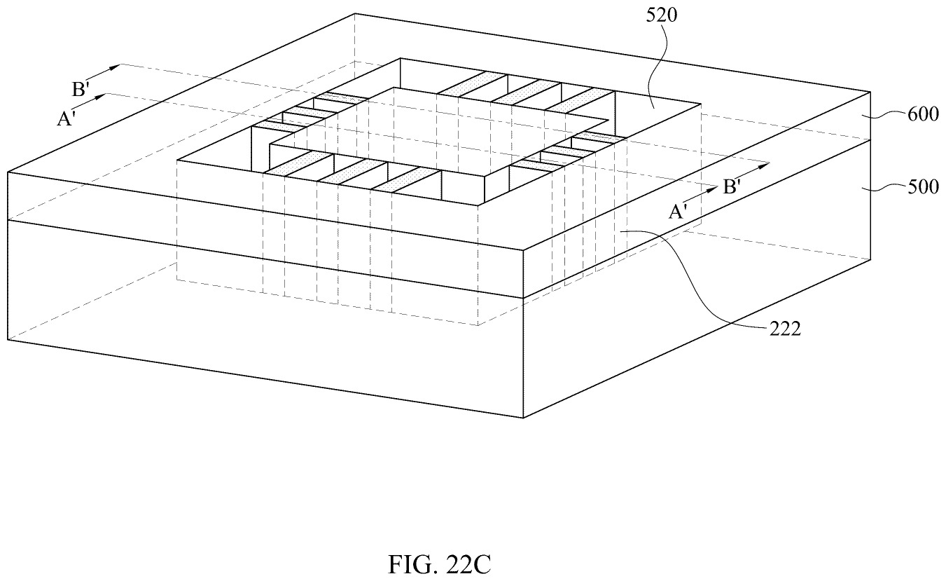

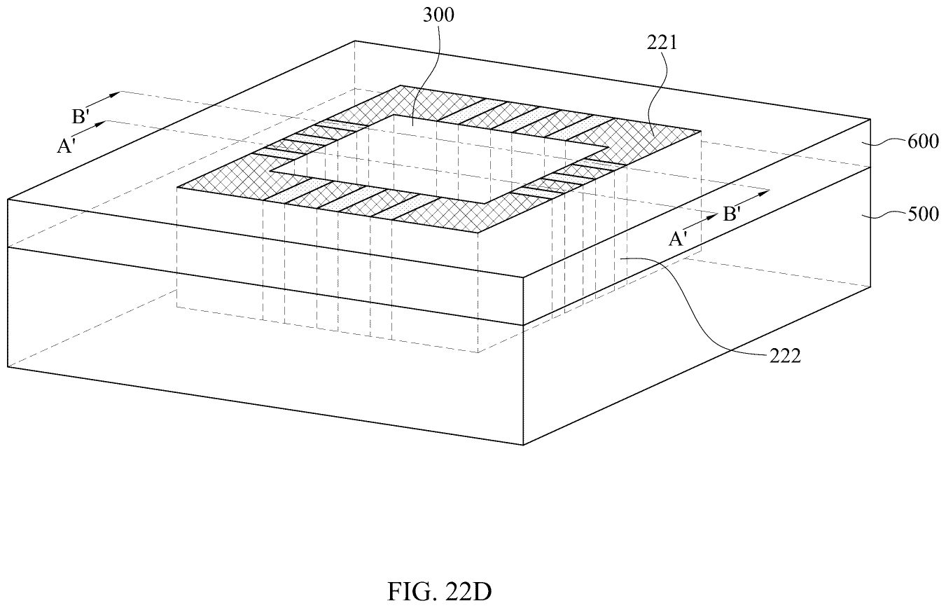

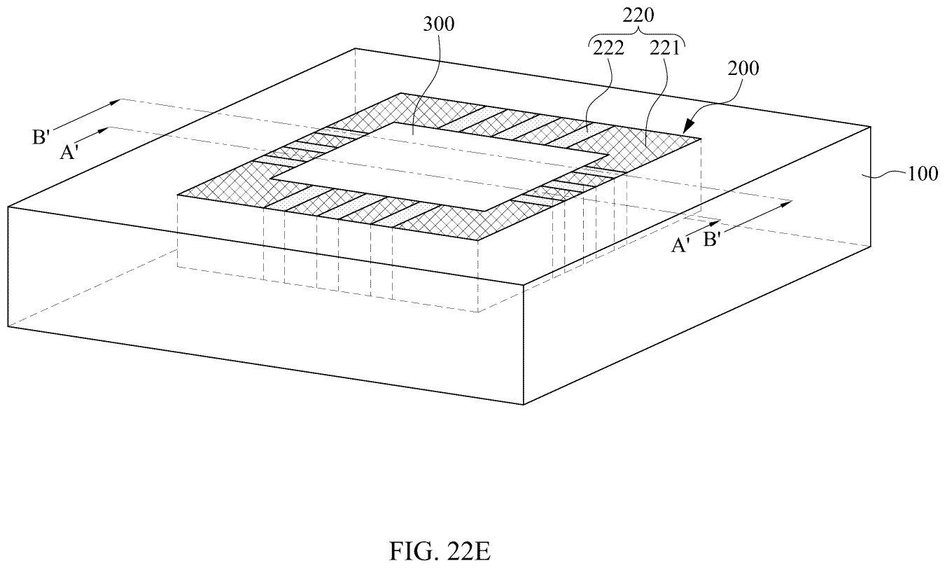

FIG. 21 is a flowchart representing a method 800 for forming a semiconductor device according to various aspects of the present disclosure. In some embodiments, the method 800 for forming the semiconductor device includes a number of operations (801, 802, 803 and 804). The method 800 for forming the semiconductor device will be further described according to one or more embodiments. It should be noted that the operations of the method 800 may be rearranged or otherwise modified within the scope of the various aspects. It should further be noted that additional processes may be provided before, during, and after the method 800, and that some other processes may be only briefly described herein. FIGS. 22A to 22E are diagrammatic perspective views illustrating various stages in the method 800 for forming the connecting structure according to aspects of one or more embodiments of the present disclosure.

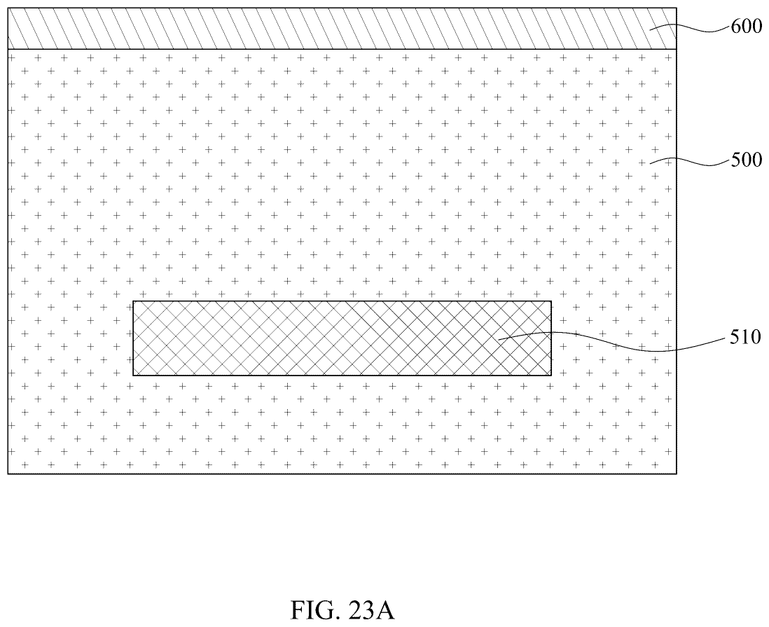

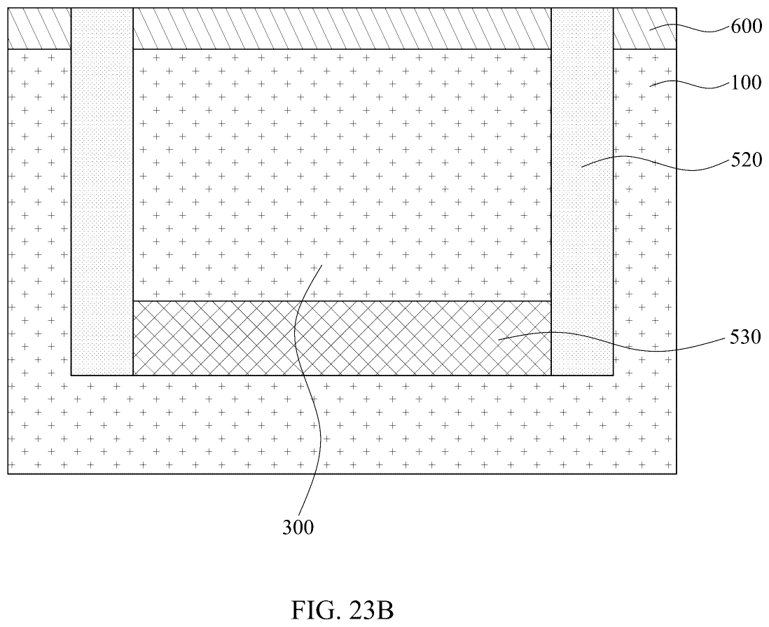

With reference to FIGS. 22A and 23A, the method 800 begins at operation 801 where an embedded doped region 510 is formed in a substrate 500 covered with a sacrificial layer 600. The process details of operation 801 is similar to those of operation 401, and hence are not repeated herein.

As shown in FIGS. 22B and 23B, the method 800 continues with operation 802 where a plurality of doped regions 222 are formed at intervals or continuously by implanting the substrate 500 surrounding the embedded doped region 510 at a depth aligned with a bottom of the embedded doped region 510 or even below the bottom of the embedded doped region 510 to ensure sufficient isolation effect.

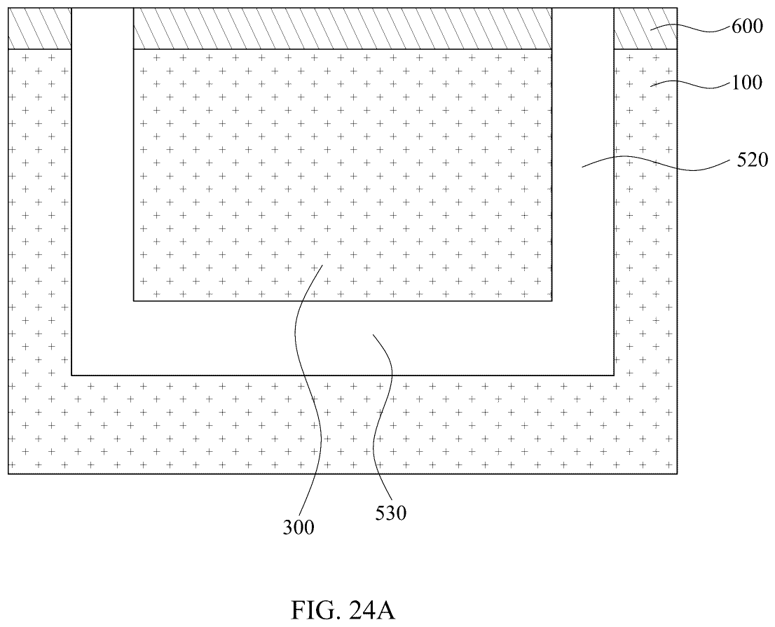

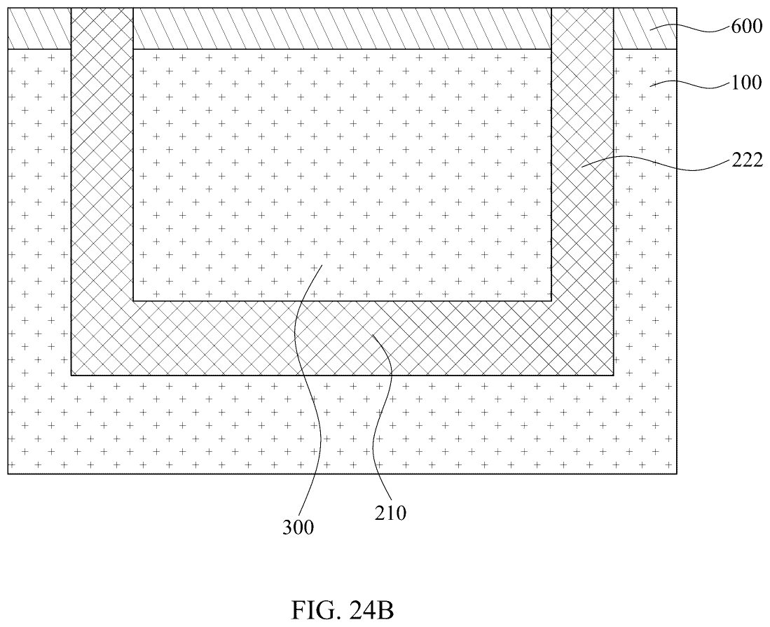

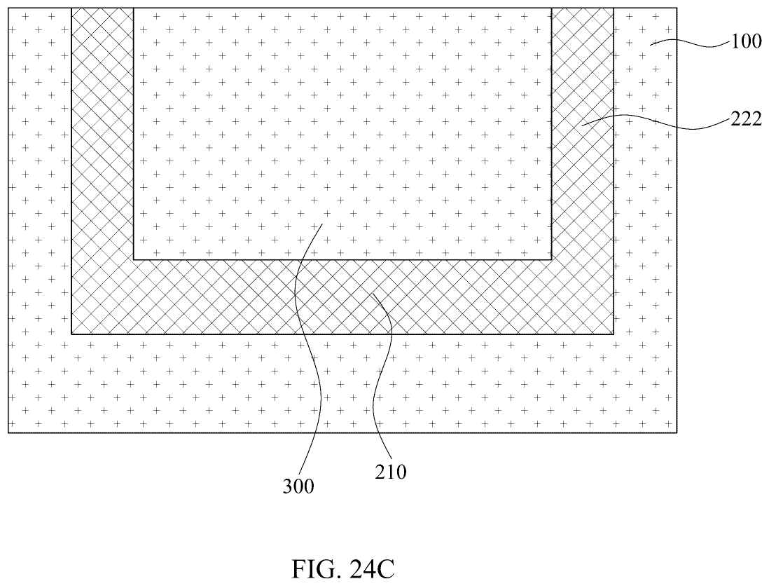

At operation 803, with reference to FIGS. 22C and 24A, a plurality of trenches 520 are formed at intervals by etching the substrate 500 from the top of the substrate 500 downwardly to a depth aligned with a bottom of the embedded doped region 510 to surround the embedded doped region 510; and the embedded doped region 510 is etched through the trenches 520 to form a lateral tunnel 530 as shown in FIG. 23B, which communicate the plurality of trenches 520, so that the trenches 520 and the doped regions 222 are formed alternately and surround the embedded doped region 510. The etching of the plurality of trenches 520 and the embedded doped region 510 is similar to that described for operation 402, and hence is not repeated herein.

At operation 804, with reference to FIGS. 22D and 24B, an isolation structure 200 can be formed by filling the lateral tunnel 530 with insulating materials to form an isolation bottom 210 and filling a plurality of doped regions 222 with insulating materials to form insulating regions 221 between the doped regions 222. The insulating regions 221 and the doped regions 222 constitute an isolation ring 220, so that the substrate 500 is divided into a first semiconductive region 100 and a second semiconductive region 300 by the isolation structure 200. Therefore, the first semiconductive region 100 is insulated from the second semiconductive region 300 through the isolation structure 200 including the isolation bottom 210 and the isolation ring 220.

Before conducting following procedures, the sacrificial layer 600 can be removed as shown in FIGS. 22E and 24C to expose a top of the first semiconductive region 100, a top of the second semiconductive region 300 and a top of the isolation ring 220.

The isolation structure 200 provides a better isolation on full direction and less parasitic effect. Further, the alternating insulating regions 221 and doped regions 222 would make the semiconductor device of the present disclosure cost-effective. There is no extra mask needed when forming the insulating regions 221 using etching and fill-in techniques and forming the doped regions 222 using implantation to achieve cost effective.

In some embodiments, a semiconductor device comprises a first semiconductive region; a second semiconductive region; and an isolation structure formed between the first semiconductive region and the second semiconductive region and comprising: an isolation bottom formed beneath the second semiconductive region; and an isolation ring with a lower portion connecting the isolation bottom and an upper portion surrounding the second semiconductive region, wherein the isolation ring comprises a plurality of insulating regions and a plurality of doped regions formed alternately; wherein the isolation bottom and the plurality of insulating regions have insulating materials; and wherein the plurality of doped regions have dopants of a conductivity type complementary to those of the first semiconductive region and the second semiconductive region.

In some embodiments, a semiconductor device comprises a first semiconductive region; a second semiconductive region; and an isolation structure formed between the first semiconductive region and the second semiconductive region and comprising: an isolation bottom 210 formed beneath the second semiconductive region and comprises insulating materials; and an isolation ring with a lower portion connecting the isolation bottom and an upper portion surrounding the second semiconductive region, wherein the isolation ring comprises a plurality of doped insulating regions and a plurality of doped regions formed alternately, wherein the plurality of doped regions have dopants of a conductivity type complementary to that of the first semiconductive region and the second semiconductive region; wherein each of the plurality of doped insulating regions comprises insulating materials and a doped portion having dopants substantially identical to dopants doped in the plurality of doped regions.

In some embodiments, a method for forming a semiconductor device comprises forming an embedded doped region in a substrate; forming an isolation structure comprising forming a plurality of trenches in the substrate and a lateral tunnel in the embedded doped region; filling the plurality of trenches and the lateral tunnel with insulating materials to form a plurality of insulating regions and an isolation bottom, which connect with each other; and forming a plurality of doped regions in the substrate between the plurality of insulating regions, wherein the substrate is divided into a first semiconductive region and a second semiconductive region by the isolation bottom and an isolation ring including the plurality of insulating regions and the plurality of doped regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor device, comprising:
a first semiconductive region;
a second semiconductive region; and
an isolation structure formed between the first semiconductive region and the second semiconductive region and comprising:
an isolation bottom formed beneath the second semiconductive region; and
an isolation ring with a lower portion connecting the isolation bottom and an upper portion surrounding the second semiconductive region,
wherein the isolation ring comprises a plurality of insulating regions and a plurality of doped regions formed alternately,
wherein the isolation bottom and the plurality of insulating regions have insulating materials, and
wherein the plurality of doped regions have dopants of a conductivity type complementary to those of the first semiconductive region and the second semiconductive region.

2. The semiconductor device of claim 1, wherein the plurality of insulating regions partially overlap the plurality of doped regions, and the plurality of insulating regions comprise the dopants of the plurality of doped regions.

3. The semiconductor device of claim 1, wherein each of the plurality of the doped region has an outer surface aligned with an outer surface of an adjacent one of the plurality of insulating regions, and an inner surface aligned with an inner surface of the adjacent one of the plurality of insulating regions.

4. The semiconductor device of claim 1, wherein each of the plurality of the doped region has an outer surface expanding toward the first semiconductive region and an inner surface expanding toward the second semiconductive region, so the isolation ring has a serrated inner surface and a serrated outer surface.

5. The semiconductor device of claim 1, wherein each of the plurality of the doped region has an inner surface expanding toward the first semiconductive region and an outer surface retracted toward the first semiconductive region, so the isolation ring has a serrated inner surface and a serrated outer surface.

6. The semiconductor device of claim 1, wherein the doped region has an outer surface expanding toward the second semiconductive region and an inner surface retracted toward the second semiconductive region, so the isolation ring has a serrated inner surface and a serrated outer surface.

7. The semiconductor device of claim 1, wherein the doped region has an inner surface retracted toward the first semiconductive region and an outer surface retracted toward the second semiconductive region, so the isolation ring has a serrated inner surface and a serrated outer surface.

8. The semiconductor device of claim 1, wherein a ratio of the plurality of insulating regions to the isolation ring is from about 10 vol. % to about 90 vol. %.

9. A semiconductor device, comprising:
a first semiconductive region;
a second semiconductive region; and
an isolation structure formed between the first semiconductive region and the second semiconductive region and comprising:
an isolation bottom formed beneath the second semiconductive region and comprises insulating materials; and
an isolation ring with a lower portion connecting the isolation bottom and an upper portion surrounding the second semiconductive region,
wherein the isolation ring comprises a plurality of doped insulating regions and a plurality of doped regions formed alternately,
wherein the plurality of doped regions have dopants of a conductivity type complementary to that of the first semiconductive region and the second semiconductive region, and
wherein each of the plurality of doped insulating regions comprises insulating materials and a doped portion having dopants substantially identical to dopants doped in the plurality of doped regions.

10. The semiconductor device of claim 9, wherein the isolation bottom comprises insulating materials substantially identical to the insulating materials of the plurality of doped insulating regions.

11. The semiconductor device of claim 9, wherein the isolation ring further comprises a doped layer formed beneath a lower surface of the isolation bottom, so the doped layer is sandwiched by the isolation bottom and the first semiconductive region.

12. The semiconductor device of claim 9, wherein the isolation ring further comprises a doped layer formed on an upper surface of the isolation bottom, so the doped layer is sandwiched by the isolation bottom and the second semiconductive region.

13. The semiconductor device of claim 9, wherein a thickness of the isolation bottom is consistent from a central region to a peripheral region.

14. The semiconductor device of claim 9, wherein a thickness of the isolation bottom is gradually decreased from a peripheral region of the isolation bottom to a central region of the isolation bottom.

15. The semiconductor device of claim 9, wherein the doped portions of the plurality of doped insulating regions and the doped regions are in contact with each other.

16. A method for manufacturing a semiconductor device, comprising:
forming an embedded doped region in a substrate;
forming an isolation structure comprising:
forming a plurality of trenches in the substrate and a lateral tunnel in the embedded doped region; filling the plurality of trenches and the lateral tunnel with insulating materials to form a plurality of insulating regions and an isolation bottom, which connect with each other; and
forming a plurality of doped regions in the substrate between the plurality of insulating regions,
wherein the substrate is divided into a first semiconductive region and a second semiconductive region by the isolation bottom and an isolation ring including the plurality of insulating regions and the plurality of doped regions.

17. The method of claim 16, wherein the formation of the plurality of insulating regions and the isolation bottom is prior to the formation of the plurality of doped regions.

18. The method of claim 16, wherein the formation of the plurality of doped regions is prior to the formation of the plurality of insulating regions and the isolation bottom.

19. The method of claim 16, wherein the plurality of trenches is formed by dry etching the substrate and the lateral tunnel is formed by wet etching the embedded doped region.

20. The method of claim 16, wherein the embedded doped region has a high etching selectivity in respect to the substrate.
